(19) United States
(12) Patent Application Publication
(10) Pub. No.: US 2023/0197871 A1
(43) Pub. Date: Jun. 22, 2023

(54) LAYER ELEMENT SUITABLE AS INTEGRATED BACKSHEET FOR A BIFACIAL PHOTOVOLTAIC MODULE

(71) Applicant: Borealis AG, Vienna (AT)

(72) Inventors: Denis Yalalov, Stenungsund (SE); Qizheng Dou, Linz (AT); Minna Aarnio-Winterhof, Linz (AT); Francis Costa, Linz (AT); August Gasslander, Stenungsund (SE)

(21) Appl. No.: 17/926,228

(22) PCT Filed: May 10, 2021
(86) PCT No.: PCT/EP2021/062248

§ 371 Date: Nov. 18, 2022

(30) Foreign Application Priority Data
May 25, 2020 (EP) 20176222.6

(51) Int. Cl. H01L 31/048; H01L 31/0468; H01L 31/068; H01L 31/049; B32B 27/32; B32B 27/08

(52) U.S. Cl. CPC H01L 31/0488; B32B 27/08; B32B 27/32; H01L 31/049; H01L 31/0468; H01L 31/0481; H01L 31/0684; B32B 2250/03; B32B 2250/242; B32B 2323/04; B32B 2323/10; B32B 2457/12

(57) ABSTRACT

The invention relates to a layer element comprising at least two layers (A) and (B), wherein layer (B) has a has a total luminous transmittance of at least 80.0%, an article, preferably abifacial photovoltaic module, comprising said layer element, a process for preparing said layer element, a process for preparing a photovoltaic module comprising said layer element and the use of said layer element as integrated backsheet element of a bifacial photovoltaic module.

The present invention relates to a layer element comprising a polyethylene based layer and a polypropylene based layer with a total transparency of at least 80%, an article, preferably a photovoltaic module, such as a bifacial photovoltaic module, comprising said layer element as integrated backsheet element, a process for producing said layer element, a process for producing said photovolataic module and the use of said layer element as integrated backsheet element of a bifacial photovoltaic module.

### TECHNICAL BACKGROUND

In certain end use applications, like outdoor end use wherein temperature may vary within wide range and articles are may be exposed to sunlight, the polymeric articles have special requirements for instance with respect to mechanical properties, long-term thermal stability, especially at high temperatures, barrier properties and UV stability.

For instance photovoltaic (PV) modules, also known as solar cell modules, produce electricity from light and are used in various kinds of applications, i.a. in outdoor applications, as well known in the field. The type of the photovoltaic module can vary. The modules have typically a multilayer structure, i.e. several different layer elements which have different functions. The layer elements of the photovoltaic module can vary with respect to layer materials and layer structure. The final photovoltaic module can be rigid or flexible. The above exemplified layer elements can be monolayer or multilayer elements. Typically the layer elements of PV module are assembled in order of their functionality and then laminated together to form the integrated PV module. Moreover, there may be adhesive layer(s) between the layers of an element or between the different layer elements. The photovoltaic (PV) module can for example contain, in a given order, a protective front layer element which can be flexible or rigid (such as a glass layer element), front encapsulation layer element, a photovoltaic element, rear encapsulation layer element, a protective back layer element, which is also called a backsheet layer element and which can be rigid or flexible; and optionally e.g. an aluminium frame. Accordingly, part or all of the layer elements of a PV module, e.g. the front and rear encapsulation layer elements, and often the backsheet layer, are typically of a polymeric material, like ethylene vinyl acetate (EVA) based material, polyester based material or polyamide based material and fluoropolymer based materials.

Bifacial PV modules produce solar power from both sides of the panel. Whereas traditional opaque-backsheeted panels are monofacial, bifacial modules expose both the front and rear side of the solar cells. By producing solar power also from the rear side an increase of power output from bifacial PV modules of up to 30% compared to monofacial PV modules can be expected. Bifacial modules come in many designs. Some are framed while others are frameless. Some are dual-glass, and others use clear backsheets. Most use monocrystalline cells, but there are polycrystalline designs. The one thing that is constant is that power is produced from both sides. There are frameless, dual-glass modules that expose the rear side of cells but are not bifacial. True bifacial modules have contacts/busbars on both the front and rear sides of their cells. Prerequisite for using a PV module as a bifacial PV module is a high transparency of the layer elements on the rear side of the solar cells for increasing the power output from the rear side of the solar cells. Nevertheless, the backsheet layer element also needs to show good mechanical stability in its function as protective back layer element. Therefore, most bifacial PV modules are dual glass modules with both protective elements on front and rear side being glass elements.

The main drawback of glass-glass modules with bifacial solar cells is the weight, which makes the handling and installation tedious, also the logistic costs might be negatively affected.

Glass being a great source of Na+ ion and bifacial solar cells (especially the rear side) being sensitive to potential induced degradation (PID), the bi facial modules have tendency to show high PID degradation. Currently, industry is solving it by having PID resistant encapsulant and/or Na free glass. One alternative and cheaper solution will be replacement of rear glass by a PP based transparent backsheet. Another problem with glass-glass module is the lamination process takes longer time and also process optimization is very tedious with conventional membrane based laminators. Therefore, plate-plate laminator or autoclave based lamination are ideal to produce good quality glass-glass module. However, more than 95% of solar laminators are based on membrane based laminator and hence many module producers just cannot simply switch to bi-facial module due to this limitation. A transparent polymeric backsheet will solve this problem fully.

The problems with competitive polymeric transparent backsheet are also manifold, like high cost, week interlayer adhesion, non compatibility with different types of encapsulant and limited hydrolytic stability (especially for PET based backsheets), and environmental aspects (presence of fluorinated polymers).

There is still room for improvement in regard of a balance of properties for the layer elements on the rear side of the solar cells for a bifacial PV module. The layer elements on the rear side of the solar cells should show a high transparency.

In the present invention a layer element is provided which comprises a polyethylene based layer and a polypropylene based layer with a high total transparency. Said layer element can be used as an integrated backsheet element for a PV module. When using said integrated backsheet element in a bifacial PV module a surprisingly good power output from the rear side of the solar cells has been found.

### SUMMARY OF THE INVENTION

The present invention relates to a layer element comprising at least two layers (A) and (B), wherein
layer (A) comprises a polyethylene composition (PE-A) comprising
(PE-A-a) a copolymer of ethylene, which bears silane group(s) containing units; or
(PE-A-b) a copolymer of ethylene with polar comonomer units selected from one or more of (C₁-C₆)-alkyl acrylate or (C₁-C₆)-alkyl (C₁-C₆)-alkylacrylate comonomer units, which additionally bears silane group(s) containing units,
   whereby the copolymer of ethylene (PE-A-a) is different from the copolymer of ethylene (PE-A-b); or
(PE-A-c) a copolymer of ethylene with vinyl acetate comonomer units; and
layer (B) comprises a polypropylene composition (PP-B) comprising
(PP-B-a) a random copolymer of propylene monomer units with alpha olefin comonomer units selected from ethylene and alpha-olefins having from 4 to 12 carbon atoms; or
(PP-B-b) a heterophasic copolymer of propylene which comprises,
   a polypropylene matrix component and
   an elastomeric propylene copolymer component which is dispersed in said polypropylene matrix;
wherein layer (B) has a total luminous transmittance of at least 80.0%.

Further, the invention relates to an article comprising the layer element as described above or below. Said article is preferably a photovoltaic module, most preferably a bifacial photovoltaic module.

Still further, the invention relates to a process for producing the layer element as described above or below comprising the steps of:
adhering the layers (A), (B) and optional layer (C) of the layer element together by extrusion or lamination in the configuration A-B or A-C-B; and
recovering the formed layer element.

Additionally, the invention relates to a process for producing a photovoltaic (PV) module as described above or below comprising the steps of:
assembling the photovoltaic element, the layer element and optional further layer elements to a photovoltaic (PV) module assembly;
laminating the layer elements of the photovoltaic (PV) module assembly in elevated temperature to adhere the elements together; and
recovering the obtained photovoltaic (PV) module.

Finally, the invention relates to the use of the layer element as described above or below as an integrated backsheet element of a bifacial photovoltaic module comprising a photovoltaic element and said layer element, wherein the photovoltaic element is in adhering contact with layer (A) of the layer element.

### DEFINITIONS

An olefin homopolymer is a polymer, which essentially consists of olefin monomer units of one sort. Due to impurities especially during commercial polymerization processes an olefin homopolymer can comprise up to 0.1 mol% comonomer units, preferably up to 0.05 mol% comonomer units and most preferably up to 0.01 mol% comonomer units.

In this sense a propylene homopolymer is a polymer which essentially consists of propylene monomer units and an ethylene homopolymer is a polymer which essentially consists of ethylene monomer units.

An olefin copolymer is a polymer which in addition to olefin monomer units also comprise one or more comonomer units in a minor molar amount.

Thereby, a copolymer of propylene comprises a molar majority of propylene monomer units and a copolymer of ethylene comprises a molar majority of ethylene monomer units.

An olefin random copolymer is a copolymer with a molar majority of said olefin monomer units, in which the comonomer units are randomly distributed in the polymeric chain.

A heterophasic polypropylene is a propylene-based copolymer with a crystalline matrix phase, which can be a propylene homopolymer or a random copolymer of propylene and at least one alpha-olefin comonomer, and an elastomeric phase dispersed therein. The elastomeric phase can be a propylene copolymer with a high amount of comonomer which is not randomly distributed in the polymer chain but are distributed in a comonomer-rich block structure and a propylene-rich block structure.

A heterophasic polypropylene usually differentiates from a one-phasic propylene copolymer in that it shows two distinct glass transition temperatures Tg which are attributed to the matrix phase and the elastomeric phase.

A plastomer is a polymer which combines the qualities of elastomers and plastics, such as rubber-like properties with the processing abilities of plastic.

An ethylene-based plastomer is a plastomer with a molar majority of ethylene monomer units.

A layer element in the sense of the present invention is a structure of one or more layers with a defined functionality which serves a certain purpose in an article comprising said layer element. In the field of PV modules a layer element is a structure of one or more layers which serves one of several functionalities such as outer protection (i.e. a protective front layer element or protective back layer element), encapsulation of the photovoltaic element (i.e. the front encapsulation layer element or rear encapsulation layer element) and the energy conversion (i.e. the photovoltaic element). A layer element can comprise other components, which are not layers, such as e.g. braces, spacers, frames etc.

An integrated backsheet element of a PV module is a structure of more than one layers which encompasses more than one functionality of the PV module. It is preferred that the integrated backsheet element encompasses the outer protection functionality of the protective back layer element and the encapsulation of the photovoltaic element function of the rear encapsulation layer element. These functionalities are usually encompassed by different layers of the integrated backsheet element.

A bifacial photovoltaic module is a photovoltaic module which produces solar power from the front and the rear side of the solar cells of the photovoltaic element.

Two layers being in adhering contact means that the surface of one layer is in direct contact the surface of the other layer without any layers or any spacers between these layers.

Different in the context of the present invention means that two polymers differ in at least one property or structural element.

### BRIEF DESCRIPTION OF THE FIGURES

FIG. 1 shows the configuration of a bifacial glass-glass photovoltaic module comprising two glass layers as front and rear protective layer elements.

FIG. 2 shows the configuration of a bifacial photovoltaic module comprising a glass layer as front protective layer element and one embodiment of the layer element according to the present invention as integrated backsheet element with layer (A) representing the encapsulant layer below the cell layer, layer (C) representing the tie layer and layer (B) representing the PP-based layer.

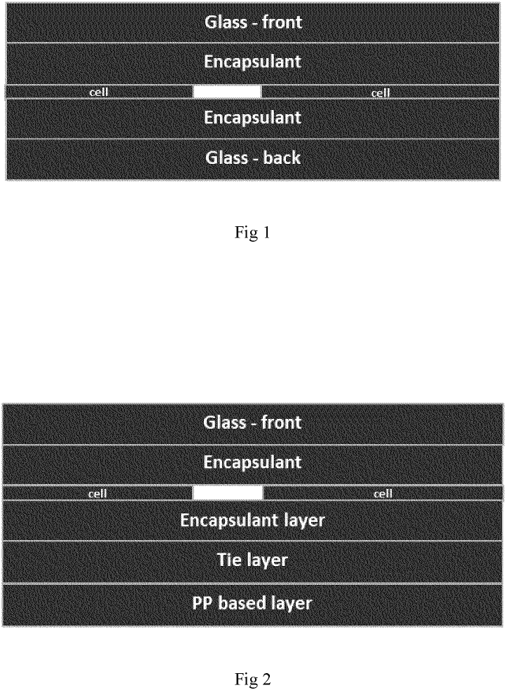

### DETAILED DESCRIPTION

### Layer Element

The layer element of the present invention comprises two layers (A) and (B).

In one embodiment the two layers (A) and (B) are in adherent contact with each other.

In said embodiment the layer element can consists of layers (A) and (B) in the configuration A-B. Then the layer element is a two-layer element.

In said embodiment the layer element alternatively comprise one or more layer(s) in addition to the layers (A) and (B). These additional layers can either be added to the surface of layer (A), which is not in adherent contact with layer (B) (i.e. layer(s) (X)), or to the surface of layer (B), which is not in adherent contact with layer (A) (i.e. layer(s) (Y)), or both (layers (X) and (Y)).

Possible configurations are X-A-B, A-B-Y and X-A-B-Y.

Layer(s) (X) can be one or more additional layers, such as 1, 2, 3 or 4 additional layer(s) (X), preferably one additional layer (X). Layer(s) (X) can be the same as layer (A) or different from layer (A).

Layer(s) (Y) can be one or more additional layers, such as 1, 2, 3 or 4 additional layer(s) (Y), preferably one additional layer (Y). Layer(s) Y can be the same as layer (B) or different from layer (B).

Usually, the layers (A) and (B) have about the same thickness.

In a two-layer element the thickness of layer (A) is preferably from 40 to 60 % of the total thickness of the two-layer element.

In a two-layer element the thickness of layer (B) is preferably from 40 to 60 % of the total thickness of the two-layer element.

The thickness ratio of the layers (A) : (B) in a two-layer element preferably ranges from 40 : 60 to 70 : 30.

In a four-layer element the thickness of each layer (X), (A), (B), (Y) preferably is independently from 15 to 35 % of the total thickness of the four-layer element.

In another embodiment, the layer element can further comprise a layer (C) in addition to layers (A) and (B).

In said embodiment the layer element comprises three layers (A), (B) and (C) in the configuration A-C-B. This means that Layer (A) is in adhering contact with layer (C) on one surface of layer (C) and layer (C) is in adhering contact with layer (B) on the other surface of layer (C). Thus, layers (A) and (B) are not in adhering contact with each other. Instead layers (A) and (B) sandwich layer (C).

In said embodiment the layer element can consist of layers (A), (B) and (C) in the configuration A-C-B. In said embodiment the layer element is a three-layer element. In said embodiment the layer element can alternatively comprise one or more layer(s) in addition to the layers (A), (B) and (C). These additional layers can either be added to the surface of layer (A), which is not in adherent contact with layer (C) (i.e. layer(s) (X)), or to the surface of layer (B), which is not in adherent contact with layer (C) (i.e. layer(s) (Y)), or both (layers (X) and (Y)).

Possible configurations are X-A-C-B, A-C-B-Y and X-A-C-B-Y.

Layer(s) (X) can be one or more additional layers, such as 1, 2, 3 or 4 additional layer(s) (X), preferably one additional layer X. Layer(s) (X) can be the same as layer (A) or different from layer (A).

Layer(s) (Y) can be one or more additional layers, such as 1, 2, 3 or 4 additional layer(s) (Y), preferably one additional layer (Y). Layer(s) (Y) can be the same as layer (B) or different from layer (B).

Usually, the layers (A) and (B) have the same or a greater thickness than layer (C). In a three-layer element the thickness of layer (A) is preferably from 30 to 50 % of the total thickness of the three-layer element.

In a three-layer element the thickness of layer (C) is preferably from 5 to 33.3 % of the total thickness of the three-layer element.

In a three-layer element the thickness of layer (B) is preferably from 30 to 50 % of the total thickness of the three-layer element.

The thickness ratio of the layers (A) : (C) : (B) in a three-layer element preferably ranges from 45 : 10 : 45 to 33.3 : 33.3 : 33.3.

In a five-layer element the thickness of each layer (X), (A), (C), (B), (Y) preferably is independently from 10 to 30 % of the total thickness of the three-layer element.

The thickness ratio of the layers (X) : (A) : (C) : (B) : (Y) in a five-layer element preferably ranges from 20 : 25 : 10 : 25 : 20 to 20 : 20 : 20 : 20 : 20.

The layer element usually has a total thickness of from 250 µm to 2000 µm, preferably from 400 µm to 1750 µm and most preferably from 600 µm to 1500 µm.

It is preferred that none of the layers of the layer element comprises titanium dioxide, preferably a pigment, as defined below. This means that preferably the layer element is free of titanium dioxide, preferably free of pigment. In some embodiments none of the layers of the layer element comprises a flame retardant as defined below.

Pigments in the sense of this application preferably are selected from mica, titanium dioxide, CaCO₃, dolomite, carbon black or any kind of coloured pigment (such as yellow, green, red, blue and so on), which could be included due to aesthetic reasons.

In regard of the optical properties has been found that the layer element shows comparably low clarity and high haze, when measured on the laminate prepared as described in the example section:

In the example section the laminates representing the layer element have a haze of from 63% to 97%.

Further, in the example section the laminates representing the layer element have a clarity of from 6% to 35%.

The layer element according to the invention preferably has the following transmittance properties, when measured on the laminate prepared as described in the example section:

The layer element has total luminous transmittance of at least 65%, more preferably at least 70%, most preferably at least 80%.

The upper limit of the total luminous transmittance is usually not more than 99%, preferably not more than 97%.

The layer element has diffuse luminous transmittance of at least 45%, more preferably at least 48%, most preferably at least 50%.

The upper limit of the diffuse luminous transmittance is usually not more than 85%, preferably not more than 80%.

Despite the rather poor optical properties of the layer element of the invention in regard of clarity and haze the layer element shows surprisingly high transmittance properties, when measured on the laminate prepared as described in the example section.

### Layer A

Layer A comprises, preferably consists of the polyethylene composition (PE-A).

The polyethylene composition (PE-A) comprises a copolymer of ethylene, which is selected from
(PE-A-a) a copolymer of ethylene, which bears silane group(s) containing units; or
(PE-A-b) a copolymer of ethylene with polar comonomer units selected from one or more of (C₁-C₆)-alkyl acrylate or (C₁-C₆)-alkyl (C₁-C₆)-alkylacrylate comonomer units, which additionally bears silane group(s) containing units,
   whereby the copolymer of ethylene (PE-A-a) is different from the copolymer of ethylene (PE-A-b); or
(PE-A-c) a copolymer of ethylene with vinyl acetate comonomer units.

The copolymers of ethylene (PE-A-a) and (PE-A-b) bear silane group(s) containing units.

The silane group(s) containing units can be present as comonomer units of the copolymer of ethylene or as a compound grafted chemically to the copolymer of ethylene. “Silane group(s) containing comonomer units” means herein above, below or in claims that the silane group(s) containing units are present in the copolymer of ethylene as a comonomer units.

In the case of silane group(s) containing units being incorporated into the copolymer of ethylene as a comonomer units, the silane group(s) containing units are copolymerized as comonomer units with ethylene monomer units during the polymerization process of copolymer of ethylene.

In the case that the silane group(s) containing units are incorporated into the copolymer of ethylene by grafting, the silane group(s) containing units are reacted chemically (also called as grafting), with the copolymer of ethylene after the polymerization of the copolymer of ethylene. The chemical reaction, i.e. grafting, is performed typically using a radical forming agent such as peroxide. Such chemical reaction may take place before or during the lamination process of the invention. In general, copolymerisation and grafting of the silane group(s) containing units to ethylene are well known techniques and well documented in the polymer field and within the skills of a skilled person.

It is also well known that the use of peroxide in the grafting embodiment decreases the melt flow rate (MFR) of an ethylene polymer due to a simultaneous crosslinking reaction. As a result, the grafting embodiment can bring limitation to the choice of the MFR of the copolymer of ethylene as a starting polymer, which choice of MFR can have an adverse impact on the quality of the polymer at the end use application. Furthermore, the by-products formed from peroxide during the grafting process can have an adverse impact on the use of the polyethylene composition (PE-A) at end use application.

The copolymerisation of the silane group(s) containing comonomer units into the polymer backbone provides more uniform incorporation of the units compared to grafting of the units. Moreover, compared to grafting, the copolymerisation does not require the addition of peroxide after the polymer is produced.

Thus, it is preferred that the silane group(s) containing units are present in copolymer of ethylene as a comonomer units.

I.e. in case of copolymer of ethylene (PE-A-a) the silane group(s) containing units are copolymerised as comonomer units together with the ethylene monomer units during the polymerisation process of the copolymer of ethylene (PE-A-a).

In the case of the copolymer of ethylene (PE-A-b) the silane group(s) containing units are copolymerised as a comonomer units together with the polar comonomer units and ethylene monomer units during the polymerisation process of the copolymer of ethylene (PE-A-b).

The silane group(s) containing units, preferably the silane group(s) containing comonomer units, of the copolymer of ethylene (PE-A-a) or the copolymer of ethylene (PE-A-b) are preferably a hydrolysable unsaturated silane compound represented by the formula (I):

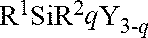

wherein
R¹ is an ethylenically unsaturated hydrocarbyl, hydrocarbyloxy or (meth)acryloxy hydrocarbyl group,
each R² is independently an aliphatic saturated hydrocarbyl group,
Y which may be the same or different, is a hydrolysable organic group and q is 0, 1 or 2;

Further suitable silane group(s) containing comonomer is e.g. gamma-(meth)acryl-oxypropyl trimethoxysilane, gamma(meth)acryloxypropyl triethoxysilane, and vinyl triacetoxysilane, or combinations of two or more thereof.

One suitable subgroup of compound of formula (I) is an unsaturated silane compound or, preferably, comonomer of formula (II)

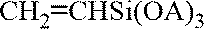

wherein each A is independently a hydrocarbyl group having 1-8 carbon atoms, suitably 1-4 carbon atoms.

The silane group(s) containing unit, or preferably, the comonomer, of the invention, is preferably the compound of formula (II) which is vinyl trimethoxysilane, vinyl bismethoxyethoxysilane, vinyl triethoxysilane, more preferably vinyl trimethoxysilane or vinyl triethoxysilane.

The amount of the silane group(s) containing units present in the based on the total amount of monomer units in the the copolymer of ethylene (PE-A-a) or the copolymer of ethylene (PE-A-b), preferably as comonomer units, is preferably in the range of from 0.01 to 1.5 mol%, more preferably from 0.01 to 1.00 mol%, still more from 0.05 to 0.80 mol%, even more preferably from 0.10 to 0.60 mol%, most preferably from 0.10 to 0.50 mo%l, based on the total amount of monomer units in the the copolymer of ethylene (PE-A-a) or the copolymer of ethylene (PE-A-b).

In one preferred embodiment the copolymer of ethylene is the copolymer of ethylene, which bears silane group(s) containing units (PE-A-a), preferably with silane group(s) containing comonomer units. In this embodiment the copolymer of ethylene (PE-A-a) does not contain, i.e. is without, a polar comonomer as defined for the copolymer of ethylene (PE-A-b). Preferably, the silane group(s) containing comonomer units are the sole comonomer units present in the copolymer of ethylene (PE-A-a). Accordingly, the copolymer of ethylene (PE-A-a) is preferably produced by copolymerising ethylene monomer units in a high pressure polymerization process in the presence of silane group(s) containing comonomer units using a radical initiator.

In said preferred embodiment the copolymer of ethylene (PE-A-a) is preferably a copolymer of ethylene with silane group(s) containing comonomer units according to formula (I), more preferably with silane group(s) containing comonomer units according to formula (II), still more preferably with silane group(s) containing comonomer units selected from vinyl trimethoxysilane, vinyl bismethoxyethoxysilane, vinyl triethoxysilane or vinyl trimethoxysilane comonomer. It is especially preferred that the copolymer of ethylene (PE-A-a) is a copolymer of ethylene with vinyl trimethoxysilane or vinyl triethoxysilane comonomer, most preferably a copolymer of ethylene with vinyl trimethoxysilane.

In another preferred embodiment the copolymer of ethylene is copolymer of ethylene with polar comonomer unit(s) selected from one or more, preferably one, of (C₁-C₆)-alkyl acrylate or (C₁-C₆)-alkyl (C₁-C₆)-alkylacrylate comonomer unit(s), which additionally bears silane group(s) containing units (PE-A-b). Preferably, the silane group(s) containing units are present as comonomer units. In this embodiment the copolymer of ethylene (PE-A-b) is thus preferably a copolymer of ethylene with polar comonomer(s) units selected from one or more, preferably one, of (C₁-C₆)-alkyl acrylate or (C₁-C₆)-alkyl (C₁-C₆)-alkylacrylate; and with silane group(s) containing comonomer units. Preferably, the polar comonomer units and the silane group(s) containing comonomer units are the sole comonomer units present in the copolymer of ethylene (PE-A-b). Accordingly, the copolymer of ethylene (PE-A-b) is preferably produced by copolymerising ethylene monomer units in a high pressure polymerization process in the presence of polar comonomer units and silane group(s) containing comonomer units using a radical initiator.

Preferably, the polar comonomer units of the copolymer of ethylene (PE-A-b) are selected from (C₁-C₆)-alkyl acrylate comonomer units, more preferably from methyl acrylate (MA), ethyl acrylate (EA) or butyl acrylate (BA) comonomer units, most preferably from methyl acrylate comonomer units.

Without binding to any theory, for instance, methyl acrylate (MA) is the only acrylate which cannot go through the ester pyrolysis reaction, since does not have this reaction path. Therefore, the copolymer of ethylene (PE-A-b) with MA comonomer units does not form any harmful free acid (acrylic acid) degradation products at high temperatures, whereby the copolymer of ethylene (PE-A-b) comprising methyl acrylate comonomer units contributes to good quality and life cycle of the end article thereof. This is not the case e.g. with vinyl acetate units of EVA, since EVA forms harmful acetic acid degradation products at high temperatures. Moreover, the other acrylates like ethyl acrylate (EA) or butyl acrylate (BA) can go through the ester pyrolysis reaction, and if degrade, would form volatile olefinic by-products.

The amount of the polar comonomer units present in the copolymer of ethylene (PEA-b) is preferably in the range of from 0.5 to 30.0 mol%, preferably from 2.5 to 20.0 mol%, still more preferably from 5.0 to 15.0 mo%l, most preferably from 7.5 to 12.5 mol%, based on the total amount of monomer units in the copolymer of ethylene (PE-A-b).

It is preferred that the copolymer of ethylene (PE-A-b) is a copolymer of ethylene with methyl acrylate, ethyl acrylate or butyl acrylate comonomer units and with vinyl trimethoxysilane, vinyl bismethoxyethoxysilane, vinyl triethoxysilane or vinyl trimethoxysilane comonomer units, more preferably with vinyl trimethoxysilane or vinyl triethoxysilane comonomer units.

More preferably the copolymer of ethylene (PE-A-b) is a copolymer of ethylene with methyl acrylate comonomer units and with vinyl trimethoxysilane, vinyl bismethoxyethoxysilane, vinyl triethoxysilane or vinyl trimethoxysilane comonomer, still more preferably a copolymer of ethylene with methyl acrylate comonomer units and with vinyl trimethoxysilane or vinyl triethoxysilane comonomer units, most preferably a copolymer of ethylene with methyl acrylate comonomer units with vinyl trimethoxysilane.

The polyethylene composition (PE-A) enables, if desired, to decrease the melt flow rate (MFR) of the copolymer of ethylene (PE-A-a) or copolymer of ethylene (PE-A-b) compared to prior art and thus offers higher resistance to flow during the production of the layer (A) and the layer element of the invention. As a result, the preferable MFR can further contribute, if desired, to the quality of the layer element, and to article, preferably the PV module, comprising the layer element.

The melt flow rate, MFR₂, of the copolymer of ethylene (PE-A-a) or copolymer of ethylene (PE-A-b) is preferably less than 20 g/10 min, preferably less than 15 g/10 min, more preferably from 0.1 to 13 g/10 min, still more preferably from 0.5 to 10 g/10 min, even more preferably from 1.0 to 8.0 g/10 min, more preferably from 1.5 to 6.0 g/10 min.

The copolymer of ethylene (PE-A-a) or copolymer of ethylene (PE-A-b) preferably has a Shear thinning index, SHI_{0.05/300}, of from 30.0 to 100.0, more preferably from 40.0 to 80.0 and most preferably from 50.0 to 75.0.

The preferable SHI range further contributes to the advantageous rheological properties of the polyethylene composition (PE-A).

Accordingly, the combination of the preferable MFR range and the preferable SHI range of the polyethylene composition (PE-A) further contributes to the quality of the layer A and the layer element of the invention. As a result, the preferable MFR can further contribute, if desired, to the quality of the layer element, and to article, preferably PV module, comprising the layer element.

The copolymer of ethylene (PE-A-a) or copolymer of ethylene (PE-A-b) preferably has a melting temperature of from 70 to 120° C., more preferably from 75° C. to 110° C., still more preferably from 80° C. to 100° C. and most preferably from 85° C. to 95° C. The preferable melting temperature is beneficial for instance for a lamination process, since the time of the melting/softening step can be reduced.

Preferably the density of the copolymer of ethylene (PE-A-a) or copolymer of ethylene (PE-A-b) is from 920 to 960 kg/m³, preferably from 925 to 955 kg/m³ and most preferably from 930 to 950 kg/m³.

The copolymer of ethylene (PE-A-a) or copolymer of ethylene (PE-A-b) can be e.g. commercially available or can be prepared according to or analogously to known polymerization processes described in the chemical literature.

In a preferred embodiment the copolymer of ethylene (PE-A-a) or copolymer of ethylene (PE-A-b) is produced by polymerising ethylene suitably with silane group(s) containing comonomer units as defined above, and in case of the copolymer of ethylene (PE-A-b) also with the polar comonomer units as described above, in a high pressure (HP) process using free radical polymerization in the presence of one or more initiator(s) and optionally using a chain transfer agent (CTA) to control the MFR of the polymer.

A suitable high pressure (HP) process with suitable polymerization conditions is described in WO 2018/141672.

Such HP polymerisation results in a so called low density polymer of ethylene (LDPE), herein to copolymer of ethylene (PE-A-a) or copolymer of ethylene (PE-A-b). The term LDPE has a well-known meaning in the polymer field and describes the nature of polyethylene produced in HP, i.e. the typical features, such as different branching architecture, to distinguish the LDPE from PE produced in the presence of an olefin polymerisation catalyst (also known as a coordination catalyst). Although the term LDPE is an abbreviation for low density polyethylene, the term is understood not to limit the density range, but covers the LDPE-like HP polyethylenes with low, medium and higher densities.

In another preferred embodiment the polyethylene composition (PE-A) comprises a copolymer of ethylene monomer units and vinyl acetate comonomer units (EVA) (PE-A-c).

The amount of the vinyl acetate (VA) comonomer units present in the copolymer of ethylene (PE-A-c) is preferably in the range of from 0.5 to 30.0 mo%l, preferably from 2.5 to 20.0 mol%, still more preferably from 5.0 to 15.0 mol%, most preferably from 7.5 to 12.5 mo%l, based on the total amount of monomer units in the copolymer of ethylene (PE-A-c).

The melt flow rate, MFR₂, of the copolymer of ethylene (PE-A-c) is preferably from 0.1 to 13 g/10 min, still more preferably from 1.0 to 50 g/10 min, more preferably from 5.0 to 45.0 g/10 min, more preferably from 7.5 to 40.0 g/10 min, most preferably from 10.0 to 35.0 g/10 min, when determined according to ISO 1133 at 190° C. and at a load of 2.16 kg.

The copolymer of ethylene (PE-A-c) preferably has a melting temperature of from 25 to 95° C., more preferably from 30° C. to 90° C., still more preferably from 35° C. to 85° C. and most preferably from 40° C. to 80° C. The preferable melting temperature is beneficial for instance for a lamination process, since the time of the melting/softening step can be reduced.

Preferably the density of the copolymer of ethylene (PE-A-c) is from 940 to 975 kg/m³, preferably from 945 to 970 kg/m³ and most preferably from 950 to 965 kg/m³.

The copolymer of ethylene (PE-A-c) usually is commercially available but can be prepared according to or analogously to known polymerization processes described in the chemical literature.

Suitable commercially available copolymers of ethylene (PE-A-c) can be purchased e.g. from Hangzhou First Applied Material Co., Ltd (PR China).

The polyethylene composition (PE-A) preferably comprises the copolymer of ethylene (PE-A-a), (PE-A-b) or (PE-A-c) in an amount of from 20.0 wt% to 100 wt%, more preferably from 20.0 wt% to 99.9999 wt%, still more preferably from 65.0 to 99.999 and most preferably from 87.5 wt% to 99.99 wt%, based on the total weight amount of the polyethylene composition (PE-A).

The amount of the copolymer of ethylene (PE-A-a), (PE-A-b) or (PE-A-c) in the polyethylene composition (PE-A) depends on the presence of additional components in the polyethylene composition (PE-A).

The polyethylene composition (PE-A) suitably comprises additive(s) which are other than filler, pigment, carbon black or flame retardant which terms have a well-known meaning in the prior art.

The optional additives are e.g. conventional additives suitable for the desired end application and within the skills of a skilled person, including without limiting to, preferably at least antioxidant(s), UV light stabilizer(s) and/or UV light absorbers, and may also include metal deactivator(s), clarifier(s), brightener(s), acid scavenger(s), as well as slip agent(s) etc. Each additive can be used e.g. in conventional amounts, the total amount of additives present in the PE composition (PE-A) being preferably as defined below. Such additives are generally commercially available and are described, for example, in “Plastic Additives Handbook”, 5th edition, 2001 of Hans Zweifel.

The amount of additives is preferably in the range of from up to 10.0 wt%, such as 0.0001 to 10.0 wt%, more preferably 0.001 and 5.0 wt%, most preferably 0.01 to 2.5 wt%, based on the total weight amount of the polyethylene composition (PE-A).

The polyethylene composition (PE-A) can further comprise flame retardants.

Optional flame retardants are typically conventional and commercially available. Suitable optional flame retardants are as defined herein in context of the layer C to fillers.

The amount of flame retardants is preferably in the range of from up to 40.0 wt%, such as 0.1 to 40.0 wt%, preferably 0.5 to 30.0 wt%, most preferably 1.0 to 15.0 wt%, based on the total weight amount of the polyethylene composition (PE-A).

The polyethylene composition (PE-A) can further comprise polymers which are different from the copolymer of ethylene (PE-A-a) or (PE-A-b) or (PE-A-c).

It is however preferred that the polyethylene composition (PE-A) comprises the copolymer of ethylene (PE-A-a) or (PE-A-b) or (PE-A-c) as the only polymeric component(s).

“Polymeric component(s)” exclude herein any carrier polymer(s) of optional additive or filler, e.g. carrier polymer(s) used in master batch(es) of additive or, respectively, filler optionally present in the polyethylene composition (PE-A). Such optional carrier polymer(s) are calculated to the amount of the respective additive or, respectively filler based on the amount (100 wt%) of the polyethylene composition (PE-A).

In an especially preferred embodiment, the polyethylene composition (PE-A) is free of fillers, pigments and/or carbon black.

The absence of fillers, pigments and/or carbon black has been found to increase the transparency of layer (A) which helps to improve the power output of a bifacial photovoltaic module.

It is further preferred that the polyethylene composition (PE-A) is additionally free of flame retardants as defined above. In said embodiment the polyethylene composition (PE-A) is preferably free of fillers, pigments, carbon black and/or flame retardants.

In one embodiment the polyethylene composition (PE-A) comprises, preferably consists of,
70.0 to 99.9999 wt%, preferably 80.0 to 99.499 wt%, most preferably 87.5 to 98.99 wt% of the copolymer of ethylene;
0.0001 to 10.0 wt%, preferably 0.001 and 5.0 wt%, most preferably 0.01 and 2.5 wt% of additives and
0 to 20.0 wt%, preferably 0.5 to 15.0 wt%, most preferably 1.0 to 10.0 wt% of flame retardant.

In said embodiment the polyethylene composition (PE-A) usually has the same ranges of the properties of melt flow rate MFR₂ and shear thinning index SHI_{0.05/300} as defined for the copolymer of ethylene (PE-A-a), copolymer of ethylene (PE-A-b) or copolymer of ethylene (PE-A-c) above.

In another embodiment the polyethylene composition (PE-A) comprises additives but no flame retardant as defined above. Then, the polyethylene composition (PE-A), comprises, preferably consists of, based on the amount (100 wt%) of the polyethylene composition (PE-A),
90.0 to 99.9999 wt%, preferably 95.0 to 99.999 wt%, most preferably 97.5 to 99.99 of the copolymer of ethylene; and
0.0001 to 10.0 wt%, preferably 0.001 and 5.0 wt%, most preferably 0.01 and 2.5 wt%, of the additives.

In said embodiment the polyethylene composition (PE-A) usually has the same ranges of the properties of melt flow rate MFR₂, density, melting temperature Tm and shear thinning index SHI_{0.05/300} as defined for the copolymer of ethylene (PE-A-a), copolymer of ethylene (PE-A-b) or copolymer of ethylene (PE-A-c) above.

This embodiment is especially preferred for the polyethylene composition (PE-A) of the layer element of the present invention.

Preferably the layer A of the layer element consists of the polyethylene composition (PE-A) comprising the copolymer of ethylene as defined above, below or in claims.

The layer (A), preferably the polyethylene composition (PE-A), most preferably the copolymer of ethylene (PE-A-a) or (PE-A-b), is preferably not crosslinked using peroxide. When using the copolymer of ethylene (PE-A-c), the layer (A), preferably the polyethylene composition (PE-A), most preferably the copolymer of ethylene (PE-A-c), can be crosslinked using peroxide, preferably in the presence of an organic peroxide. The crosslinking process and conditions are well known in the art and depend on the nature of the used peroxide.

However, if desired, depending on the end application, the polyethylene composition (PE-A) can be crosslinked via the silane group(s) containing units of the copolymer of ethylene (PE-A-a) or copolymer of ethylene (PE-A-b) using a silanol condensation catalyst (SCC), which is preferably selected from the group of carboxylates of tin, zinc, iron, lead or cobalt or aromatic organic sulphonic acids, before or during the lamination process of the layer element of the invention. Such SCCs are for instance commercially available.

It is to be understood that the SCC as defined above are those conventionally supplied for the purpose of crosslinking.

The amount of the optional crosslinking agent (SCC), if present, is preferably of 0 to 0.1 mol/kg, like 0.00001 to 0.1, preferably of 0.0001 to 0.01, more preferably 0.0002 to 0.005, more preferably of 0.0005 to 0.005, mol/kg copolymer of ethylene. Preferably no crosslinking agent (SCC) is present in the layer element (LE).

In a preferred embodiment no silane condensation catalyst (SCC), which is selected from the SCC group of tin-organic catalysts or aromatic organic sulphonic acids, is present in the polyethylene composition (PE-A). In a further preferred embodiment no peroxide or silane condensation catalyst (SCC), as defined above, is present in the polyethylene composition (PE-A).

It is especially preferred that the polyethylene composition is not crosslinked.

As already mentioned, with the polyethylene composition (PE-A) crosslinking of layer (A) of the layer element can be avoided which contributes to achieve the good quality of the layer element.

Layer (A) preferably has a thickness of from 100 µm to 750 µm, preferably from 150 µm to 650 µm, most preferably from 200 µm to 550 µm.

### Layer (B)

Layer (B) comprises a polypropylene composition (PP-B) comprising
(PP-B-a) a random copolymer of propylene monomer units with alpha olefin comonomer units selected from ethylene and alpha-olefins having from 4 to 12 carbon atoms; or
(PP-B-b) a heterophasic copolymer of propylene which comprises,
   a polypropylene matrix component and
   an elastomeric propylene copolymer component which is dispersed in said polypropylene matrix;
wherein layer (B) has a total luminous transmittance of at least 80.0%.

In one embodiment the polypropylene composition (PP-B) comprises a random copolymer of propylene monomer units with alpha olefin comonomer units selected from ethylene and alpha-olefins having from 4 to 12 carbon atoms (PP-B-a).

The comonomer units are selected from ethylene and alpha-olefins having from 4 to 12 carbon atoms, preferably from ethylene and alpha-olefins having from 4 to 8 carbon atoms, more preferably from ethylene, 1-butene and 1-hexene, still more preferably from ethylene and 1-butene and most preferably from ethylene.

Preferably, the random copolymer (PP-B-a) only includes one sort of comonomer units as described above. In this case the random copolymer is a random copolymer of propylene monomer units with alpha olefin comonomer units selected from one of ethylene and alpha-olefins having from 4 to 12 carbon atoms.

Alternatively, the random copolymer (PP-B-a) includes more than one sort of comonomer units as described above, such as two or three. In this case the random copolymer is a random copolymer of propylene monomer units with two or more, such as two or three, alpha olefin comonomer units selected from one of ethylene and alpha-olefins having from 4 to 12 carbon atoms.

The comonomer content in the random copolymer (PP-B-a) in preferably the range of from 0.5 to 15.0 wt%, more preferably in the range of from more than 1.0 wt% to 12.5 wt%, even more preferably in the range of from 1.5 to 10.0 wt%, still most preferably in the range of from 2.0 to 8.0 wt.

The random copolymer (PP-B-a) preferably has a melt flow rate MFR₂ (230° C.) measured according to ISO 1133 in the range of from 0.5 to 20.0 g/10 min, more preferably in the range of from 1.0 to 15.0 g/10 min, even more preferably in the range of from 1.5 to 12.0 g/10 min, still more preferably in range of from 1.8 to 10.0 g/10.

Further, the random copolymer (PP-B-a) can be defined by the xylene cold soluble (XCS) content measured according to ISO 6427. Accordingly the propylene polymer is preferably featured by a xylene cold soluble (XCS) content of below 25.0 wt%, more preferably of below 20.0 wt%.

Thus it is in particular appreciated that the random copolymer (PP-B-a) has a xylene cold soluble (XCS) content in the range of 2.0 to below 20.0 wt %, most preferably in the range of 3.0 to 18.0 wt%.

Still further, the random copolymer (PP-B-a) can be defined by the melting temperature (Tm). Accordingly the propylene polymer preferably has a melting temperature Tm of equal to or higher than 120° C. Even more preferable the melting temperature Tm is in the range of 125° C. to 160° C., most preferably in the range of 125° C. to 155° C.

The random copolymer (PP-B-a) preferably has a density in the range of from 900 to 910 kg/m³.

The crystallisation temperature measured via DSC according to ISO 11357 of the random copolymer (PP-B-a) can be equal or higher than 85° C., preferably in the range of 85° C. to 150° C., and even more preferably in the range of 90° C. to 130° C.

The random copolymer (PP-B-a) can be further unimodal or multimodal, like bimodal in view of the molecular weight distribution and/or the comonomer content distribution; both unimodal and bimodal propylene polymers are equally preferred.

If the random copolymer (PP-B-a) is unimodal, it is preferably produced in a single polymerization step in one polymerization reactor (R1). Alternatively a unimodal propylene polymer can be produced in a sequential polymerization process using the same polymerization conditions in all reactors.

If the propylene polymer is multimodal, it is preferably produced in a sequential polymerization process using different polymerization conditions (amount of comonomer, hydrogen amount, etc.) in the reactors. In some embodiments, a propylene homopolymer fraction is polymerized in one reaction step and a propylene copolymer fraction is polymerized in a second reaction step of a sequential polymerization process.

The random copolymer (PP-B-a) is preferably the propylene polymer is produced in the presence of a Ziegler-Natta catalyst system or a single site catalyst system, such as a metallocene catalyst system. Suitable catalyst systems are the same as discussed below for the heterophasic copolymer of propylene (PP-B-b).

The random copolymer (PP-B-a) can be produced in a single polymerization step comprising a single polymerization reactor (R1) or in a sequential polymerization process comprising at least two polymerization reactors (R1) and (R2), whereby in the first polymerization reactor (R1) a first propylene polymer fraction is produced, which is subsequently transferred into the second polymerization reactor (R2). In the second polymerization reactor (R2) a second propylene polymer fraction is then produced in the presence of the first propylene polymer fraction.

Polymerization processes which are suitable for producing the random copolymer (PP-B-a) generally comprises one or two polymerization stages and each stage can be carried out in solution, slurry, fluidized bed, bulk or gas phase.

The term “polymerization reactor” shall indicate that the main polymerization takes place. Thus in case the process consists of one or two polymerization reactors, this definition does not exclude the option that the overall system comprises for instance a pre-polymerization step in a pre-polymerization reactor. The term “consist of” is only a closing formulation in view of the main polymerization reactors.

The term “sequential polymerization process” indicates that the random copolymer (PP-B-a) is produced in at least two reactors connected in series. Accordingly such a polymerization system comprises at least a first polymerization reactor (R1) and a second polymerization reactor (R2), and optionally a third polymerization reactor (R3).

The first, respectively the single, polymerization reactor (R1) is preferably a slurry reactor and can be any continuous or simple stirred batch tank reactor or loop reactor operating in bulk or slurry. Bulk means a polymerization in a reaction medium that comprises of at least 60 % (w/w) monomer. According to the present invention the slurry reactor is preferably a (bulk) loop reactor.

In case a “sequential polymerization process” is applied the second polymerization reactor (R2) and the optional third polymerization reactor (R3) are gas phase reactors (GPRs), i.e. a first gas phase reactor (GPR1) and a second gas phase reactor (GPR2). A gas phase reactor (GPR) according to this invention is preferably a fluidized bed reactor, a fast fluidized bed reactor or a settled bed reactor or any combination thereof.

A preferred multistage process is a “loop-gas phase″-process, such as developed by Borealis (known as BORSTAR® technology) described e.g. in patent literature, such as in EP 0 887 379, WO 92/12182, WO 2004/000899, WO 2004/111095, WO 99/24478, WO 99/24479 or in WO 00/68315.

A further suitable slurry-gas phase process is the Spheripol® process of Basell.

Suitable polymerization conditions are the same as discussed below for the polypropylene matrix component of the heterophasic copolymer of propylene (PP-B-b).

In another embodiment, the polypropylene composition (PP-B) comprises a heterophasic copolymer of propylene which comprises a polypropylene matrix component and an elastomeric propylene copolymer component which is dispersed in said polypropylene matrix (PP-B-b).

The matrix component of the heterophasic copolymer of propylene (PP-B-b) can be a propylene homopolymer component or a propylene random copolymer component.

When being a propylene random copolymer component, the matrix component is preferably a random copolymer of propylene with one or more of ethylene and/or C₄-C₈ alpha olefin comonomers. It is preferred that said propylene random copolymer component is a propylene-ethylene random copolymer.

Preferably, the polypropylene matrix component of the heterophasic copolymer of propylene (PP-B-b) is a homopolymer of propylene.

The XCS fraction of the heterophasic copolymer of propylene (PP-B-b) is regarded herein as the elastomeric component, since the amount of XCS fraction in the matrix component is conventionally markedly lower. For instance, in case the matrix component is a homopolymer of propylene, then the weight amount of the xylene cold soluble (XCS) fraction of the heterophasic copolymer of propylene (PP-B-b) is understood in this application also as the amount of the elastomeric propylene copolymer component present in the heterophasic copolymer of propylene (PP-B-b).

The total comonomer content of the heterophasic copolymer of propylene (PP-B-b) is preferably from 2.0 to 25.0 wt%, more preferably from 3.0 to 20.0 wt%.

It is preferred that the comonomer units of the heterophasic copolymer of propylene (PP-B-b) are selected from ethylene and/or C₄-C₈ alpha olefin comonomers, more preferably from ethylene.

The melting temperature, Tm, of the heterophasic copolymer of propylene (PP-B-b) is preferably at least 145° C., more preferably from 150 to 170° C., most preferably from 155 to 170° C.

The Vicat softening temperature (Vicat A) of the heterophasic copolymer of propylene (PP-B-b) is preferably of at least 90° C., preferably from 105 to 160° C., most preferably from 120 to 155° C.

The heterophasic copolymer of propylene (PP-B-b) preferably has a melt flow rate MFR₂ (2.16 kg, 230° C.) of 1.0 to 20.0 g/10 min, preferably from 2.0 to 17.5 g/10 min, preferably from 3.0 to 15.0 g/10 min.

Further, the heterophasic copolymer of propylene (PP-B-b) preferably has a xylene cold soluble (XCS) fraction in amount of from 5 to 40 wt%, more preferably from 10 to 37 wt%, based on the total amount of the heterophasic copolymer of propylene (PP-B-b).

Still further, the heterophasic copolymer of propylene (PP-B-b) preferably has a flexural modulus of at least 700 MPa, preferably of 750 to 2500 MPa.

Further, the heterophasic copolymer of propylene (PP-B-b) preferably has a density of 900 to 910 kg/m³.

In a preferred embodiment, the heterophasic copolymer of propylene (PP-B-b) meets all of the above described properties of comonomer content, Tm, Vicat A, MFR₂, XCS fraction, flexural modulus and density.

The polypropylene composition (PP-B) can also comprise a mixture of two or more, e.g. two such heterophasic copolymers of propylene which are different.

The heterophasic copolymer of propylene can be a commercially available grade or can be produced e.g. by conventional polymerisation processes and process conditions using e.g. the conventional catalyst system known in the literature.

The heterophasic copolymer of propylene as described herein, can be polymerized in a sequential polymerization process, such as a multistage process.

A suitable process is described in WO 2018/141672.

A preferred multistage process is a “loop-gas phase″-process, such as developed by Borealis A/S, Denmark (known as BORSTAR® technology) described e.g. in patent literature, such as in EP 0 887 379, WO 92/12182 WO 2004/000899, WO 2004/111095, WO 99/24478, WO 99/24479 or in WO 00/68315.

A further suitable slurry-gas phase process is the Spheripol® process of LyondellBasell.

After the random copolymer of propylene (PP-B-a) or the heterophasic copolymer of propylene (PP-B-b) has been removed from the last polymerisation stage, it is preferably subjected to process steps for removing the residual hydrocarbons from the polymer. Such processes are well known in the art and can include pressure reduction steps, purging steps, stripping steps, extraction steps and so on. Also combinations of different steps are possible. After the removal of residual hydrocarbons the heterophasic copolymer of propylene is preferably mixed with additives as it is well known in the art. Such additives are described above for the polypropylene composition (PP-B). The polymer particles are then extruded to pellets as it is known in the art. Preferably co-rotating twin screw extruder is used for the extrusion step. Such extruders are manufactured, for instance, by Coperion (Werner & Pfleiderer) and Japan Steel Works.

The random copolymer of propylene (PP-B-a) or the heterophasic copolymer of propylene (PP-B-b) is preferably produced by polymerisation using any suitable Ziegler-Natta type. Typical suitable Ziegler-Natta type catalyst is stereospecific, solid high yield Ziegler-Natta catalyst component comprising as essential components Mg, Ti and Cl. In addition to the solid catalyst a cocatalyst(s) as well external donor(s) are typically used in polymerisation process.

Components of catalyst may be supported on a particulate support, such as inorganic oxide, like silica or alumina, or, usually, the magnesium halide may form the solid support. It is also possible that catalysts components are not supported on an external support, but catalyst is prepared by emulsion-solidification method or by precipitation method.

Alternatively the random copolymer of propylene (PP-B-a) or the heterophasic copolymer of propylene (PP-B-b) of the invention can be produced using a modified catalyst system as described below.

More preferably, a vinyl compound of the formula (I) is used for the modification of the catalyst:

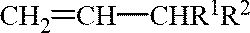

wherein R¹ and R² together form a 5- or 6-membered saturated, unsaturated or aromatic ring, optionally containing substituents, or independently represent an alkyl group comprising 1 to 4 carbon atoms, whereby in case R¹ and R² form an aromatic ring, the hydrogen atom of the —CHR¹R² moiety is not present.

More preferably, the vinyl compound (IV) is selected from: vinyl cycloalkane, preferably vinyl cyclohexane (VCH), vinyl cyclopentane, 3-methyl-1-butene polymer and vinyl-2-methyl cyclohexane polymer. Most preferably the vinyl compound (IV) is vinyl cyclohexane (VCH) polymer.

The solid catalyst usually also comprises an electron donor (internal electron donor) and optionally aluminium. Suitable internal electron donors are, among others, esters of carboxylic acids or dicarboxylic acids, like phthalates, maleates, benzoates, citraconates, and succinates, 1,3-diethers or oxygen or nitrogen containing silicon compounds. In addition mixtures of donors can be used.

The cocatalyst typically comprises an aluminium alkyl compound. The aluminium alkyl compound is preferably trialkyl aluminium such as trimethylaluminium, triethylaluminium, tri-isobutylaluminium or tri-n-octylaluminium. However, it may also be an alkylaluminium halide, such as diethylaluminium chloride, dimethylaluminium chloride and ethylaluminium sesquichloride.

Suitable external electron donors used in polymerisation are well known in the art and include ethers, ketones, amines, alcohols, phenols, phosphines and silanes. Silane type external donors are typically organosilane compounds containing Si—OCOR, Si—OR, or Si—NR₂ bonds, having silicon as the central atom, and R is an alkyl, alkenyl, aryl, arylalkyl or cycloalkyl with 1-20 carbon atoms are known in the art.

Examples of suitable catalysts and compounds in catalysts are shown in among others, in WO 87/07620, WO 92/21705, WO 93/11165, WO 93/11166, WO 93/19100, WO 97/36939, WO 98/12234, WO 99/33842, WO 03/000756, WO 03/000757, WO 03/000754, WO 03/000755, WO 2004/029112, EP 2610271, WO 2012/007430. WO 92/19659, WO 92/19653, WO 92/19658, US 4382019, US 4435550 , US 4465782, US 4473660, US 4560671, US 5539067, US5618771, EP45975, EP45976, EP45977, WO 95/32994, US 4107414, US 4186107, US 4226963, US 4347160, US 4472524, US 4522930, US 4530912, US 4532313, US 4657882, US 4581342, US 4657882.

Alternatively, the random copolymer of propylene (PP-B-a) or the heterophasic copolymer of propylene (PP-B-b) can be produced in the presence of a single-site catalyst such as a single site solid particulate catalyst free from an external carrier, preferably a catalyst comprising (i) a complex of formula (I):

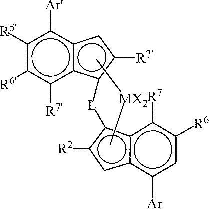

wherein
M is zirconium or hafnium;
each X is a sigma ligand;
L is a divalent bridge selected from —R′₂C—, —R′₂C—CR′₂—, —R′₂Si—, —R′₂Si—SiR′₂—, —R′₂Ge—, wherein each R′ is independently a hydrogen atom, C₁-C₂₀-hydrocarbyl, tri(C₁-C₂₀-alkyl)silyl, C₆-C₂₀-aryl, C₇-C₂₀-arylalkyl or C₇-C₂₀-alkylaryl;
R² and R²′ are each independently a C₁-C₂₀ hydrocarbyl radical optionally containing one or more heteroatoms from groups 14-16;
R^{5′} is a C₁₋₂₀ hydrocarbyl group containing one or more heteroatoms from groups 14-16 optionally substituted by one or more halo atoms;
R⁶ and R^{6′} are each independently hydrogen or a C₁₋₂₀ hydrocarbyl group optionally containing one or more heteroatoms from groups 14-16;
R⁷ and R^{7′} are each independently hydrogen or C₁₋₂₀ hydrocarbyl group optionally containing one or more heteroatoms from groups 14-16;
Ar is independently an aryl or heteroaryl group having up to 20 carbon atoms optionally substituted by one or more groups R¹;
Ar′ is independently an aryl or heteroaryl group having up to 20 carbon atoms optionally substituted by one or more groups R¹;
each R¹ is a C₁₋₂₀ hydrocarbyl group or two R¹ groups on adjacent carbon atoms taken together can form a fused 5 or 6 membered non aromatic ring with the Ar group, said ring being itself optionally substituted with one or more groups R⁴;
each R⁴ is a C₁₋₂₀ hydrocarbyl group;
and (ii) a cocatalyst comprising a compound of a group 13 metal, e.g. Al or boron compound.

The catalyst used in the process of the invention is in solid particulate form free from an external carrier. Ideally, the catalyst is obtainable by a process in which
(a) a liquid/liquid emulsion system is formed, said liquid/liquid emulsion system comprising a solution of the catalyst components (i) and (ii) dispersed in a solvent so as to form dispersed droplets; and
(b) solid particles are formed by solidifying said dispersed droplets.

Viewed from another aspect therefore, the invention provides a process for the preparation of a random copolymer of propylene (PP-B-a) or heterophasic propylene copolymer (PP-B-b) as hereinbefore defined in which the catalyst as hereinbefore defined is prepared by obtaining (i) a complex of formula (I) and a cocatalyst (ii) as hereinbefore described;

forming a liquid/liquid emulsion system, which comprises a solution of catalyst components (i) and (ii) dispersed in a solvent, and solidifying said dispersed droplets to form solid particles.

The term C₁₋₂₀ hydrocarbyl group includes C₁₋₂₀ alkyl, C₂₋₂₀ alkenyl, C₂₋₂₀ alkynyl, C₃₋₂₀ cycloalkyl, C₃₋₂₀ cycloalkenyl, C₆₋₂₀ aryl groups, C₇₋₂₀ alkylaryl groups or C₇₋₂₀ arylalkyl groups or of course mixtures of these groups such as cycloalkyl substituted by alkyl.

Unless otherwise stated, preferred C₁₋₂₀ hydrocarbyl groups are C₁₋₂₀ alkyl, C₄₋₂₀ cycloalkyl, C₅₋₂₀ cycloalkyl-alkyl groups, C₇₋₂₀ alkylaryl groups, C₇₋₂₀ arylalkyl groups or C₆₋₂₀ aryl groups, especially C₁₋₁₀ alkyl groups, C₆₋₁₀ aryl groups, or C₇₋₁₂ arylalkyl groups, e.g. C₁₋₈alkyl groups. Most especially preferred hydrocarbyl groups are methyl, ethyl, propyl, isopropyl, tertbutyl, isobutyl, C₅₋₆-cycloalkyl, cyclohexylmethyl, phenyl or benzyl.

The term halo includes fluoro, chloro, bromo and iodo groups, especially chloro groups, when relating to the complex definition.

The oxidation state of the metal ion is governed primarily by the nature of the metal ion in question and the stability of the individual oxidation states of each metal ion. It will be appreciated that in the complexes of the invention, the metal ion M is coordinated by ligands X so as to satisfy the valency of the metal ion and to fill its available coordination sites. The nature of these σ-ligands can vary greatly.

Such catalysts are described in WO2013/007650 which is incorporated herein by reference.

The polypropylene composition (PP-B) preferably comprises additives.

Herein the term additives exclude the optional filler(s), optional pigment(s) and optional flame retardant(s). Such additives are preferably conventional and commercially available, including without limiting to, UV stabilisers, antioxidants, nucleating agents, clarifiers, brighteners, acid scavengers, as well as slip agents, processing aids etc. Such additives are generally commercially available and are described, for example, in “Plastic Additives Handbook”, 5th edition, 2001 of Hans Zweifel.

Each additive can be used e.g. in conventional amounts. The suitable additives and the amounts thereof for layer (B) can be chosen by a skilled person depending on the desired article and the end use thereof.

Preferably, the additives are selected at least from UV stabiliser(s) comprising hindered amine compound and antioxidant(s) comprising a dialkyl amine compound. More preferably the additives are selected at least from UV stabiliser(s) comprising hindered amine compound and antioxidant(s) comprising a dialkyl amine compound, and wherein the additives are without phenolic unit(s). The expression “the additives are without phenolic unit(s)” means herein that any additive compound including UV stabiliser(s) and antioxidant(s) present in the polypropylene composition (PP-B) bears no phenolic units. Preferably the composition does not comprise any components, like additives, with phenolic units.

Accordingly, herein the filler(s), pigment(s) and flame retardant(s) are not understood nor defined as the additives.

Preferably the polypropylene composition (PP-B) comprises additives and/or optionally one or more selected from filler(s) and flame retardant(s).

The optional filler(s), if present, are preferably inorganic filler(s), more preferably one inorganic filler. The particle size and/or aspect ratio of the filler can vary as well-known by a skilled person. Preferably, the filler(s) is selected from one or more of wollastonite, talc or glass fiber. Such filler products are commercial products with varying particle size and/or aspect ratio and can be chosen by a skilled person depending on the desired end article and end application. The filler(s) can be e.g. conventional and commercially available. The amount of the filler(s), if present, is preferably 1 to 30 wt%, preferably 2 to 25 wt%, based on the total amount (100 wt%) of the polypropylene composition (PP-B).

The optional flame retardant(s), if present, can be e.g. any commercial flame retardant product, preferably a flame retardant comprising inorganic phosphorous. The amount of the flame retardant(s), if present, is preferably of 1 to 20 wt%, preferably 2 to 15 wt%, more preferably 3 to 12 wt%, based on the amount of the polypropylene composition (PP-B).

As a further component an alpha-nucleating agent can be present within the polypropylene composition (PP-B).

One type of preferred alpha-nucleating agents are those which are soluble in the random copolymer of propylene (PP-B-a) or the heterophasic copolymer of propylene (PP-B-b). Soluble alpha-nucleating agents are characterized by demonstrating a sequence of dissolution in heating and recrystallization in cooling to improve the degree of dispersion. Methods for determining said dissolution and recrystallization are described for example by Kristiansen et al. in Macromolecules 38 (2005) pages 10461-10465 and by Balzano et al. in Macromolecules 41 (2008) pages 5350-5355. In detail, the dissolution and recrystallization can be monitored by means of melt rheology in dynamic mode as defined by ISO 6271-10:1999.

Soluble alpha-nucleating agents can be selected from the group consisting of sorbitol derivatives, nonitol derivatives, benzene derivatives of formula N-I as defined below, like benzene-trisamides, and mixtures thereof.

Suitable sorbitol derivatives are di(alkylbenzylidene)sorbitols, like 1,3:2,4-dibenzylidenesorbitol or bis-(3,4-dimethylbenzylidene)sorbitol.

Suitable nonitol derivatives include 1,2,3-trideoxy-4,6:5,7-bis—O—[(4-propylphenyl)methylene]-nonitol.

Suitable benzene derivatives include N,N′,N″-tris-tert-butyl-1,3,5-benzenetricarboxamide or N,N′,N″-tris-cyclohexyl-1,3,5-benzene-tricarboxamide. Another type of preferred alpha-nucleating agents are polymeric alpha-nucleating agents. The polymeric alpha-nucleating agent is a polymer of a vinyl compound of the formula CH₂═CH—CHR⁶R⁷, wherein R⁶ and R⁷ together form a 5- or 6-membered saturated, unsaturated or aromatic ring or independently represent an alkyl group comprising 1 to 4 carbon atoms. Preferably the polymeric alpha-nucleating agent is a homopolymer of the vinyl compound of the formula CH₂═CH—CHR⁶R⁷.

One method for incorporating the polymeric α-nucleating agent into the polypropylene composition (PP—B) includes prepolymerising the polymerisation catalyst by contacting the catalyst with the vinyl compound of the formula CH₂═CH—CHR⁶R⁷, wherein R⁶ and R⁷ together form a 5- or 6-membered saturated, unsaturated or aromatic ring or independently represent an alkyl group comprising 1 to 4 carbon atoms. Propylene is then polymerised in the presence of such prepolymerised catalyst as discussed above.

In the prepolymerisation the catalyst is prepolymerised so that it contains up to 5 grams of prepolymer per gram of solid catalyst component, preferably from 0.1 to 4 grams of prepolymer per one gram of the solid catalyst component. Then, the catalyst is contacted at polymerisation conditions with the vinyl compound of the formula CH₂═CH—^{CHR6R7}, wherein R⁶ and R⁷ are as defined above. Especially preferably R⁶ and R⁷ then form a saturated 5- or 6-membered ring. Especially preferably the vinyl compound is vinylcyclohexane. Especially preferably the catalyst then contains from 0.5 to 2 grams of the polymerised vinyl compound, such as poly(vinylcyclohexane), per one gram of solid catalyst component. This allows the preparation of nucleated polypropylene as disclosed in EP-A-607703, EP-A-1028984, EP-A-1028985 and EP-A-1030878.

The polypropylene composition can also comprise an alpha-nucleating agent which is unsoluble in the random copolymer of propylene (PP-B-a) or the heterophasic copolymer of propylene (PP-B-b), such as talc, as a suitable alpha-nucleating agent. The polypropylene composition (PP-B) can optionally comprise up to 5.0 wt%, preferably from 0.0001 to 5.0 wt% of an alpha-nucleating agent, preferably from 0.001 to 1.5 wt%, and especially preferably from 0.01 to 1.0 wt% of an alpha-nucleating agent, based on the total weight of the polypropylene composition (PP-B).

Any optional carrier polymers of additives, of optional filler(s), of optional nucleating agent(s), e.g. master batches of said components, together with the carrier polymer, are calculated to the amount of the respective component, based on the amount (100 %) of the polypropylene composition (PP-B).

It is especially preferred that the polypropylene composition (PP-B) is free of pigment(s). The absence of pigments has been found to increase the transparency of layer (A) which helps to improve the power output of a bifacial photovoltaic module.

The polypropylene composition (PP-B) preferably is free of filler(s) as defined above.

It is especially preferred that the polypropylene composition (PP-B) is free of filler(s) as defined above, pigment(s).

In some embodiments the polypropylene composition (PP-B) is free of flame retardant(s) as defined above.

The polypropylene composition can further comprise further polymer component(s). The optional further polymer component(s) can be any polymer other than the random copolymer of propylene (PP-B-a) or the heterophasic copolymer of propylene (PP-B-b), preferably a polyolefin based polymer. Typical examples of further polymer component(s) are one or both of a plastomer or functionalised polymer, which both have a well-known meaning.

The optional plastomer, if present, is preferably a copolymer of ethylene with at least one C3 to C 10 alpha-olefin. The plastomer, if present, has preferably one or all, preferably all, of the below properties
a density of 850 to 915, preferably 860 to 910, kg/m³,
MFR₂ of 0.1 to 50, preferably 0.2 to 40 g/10min (190° C., 2.16 kg), and/or
the alpha-olefin comonomer is octene.

The optional plastomer, if present, is preferably produced using a metallocene catalyst, which term has a well-known meaning in the prior art. The suitable plastomers are commercially available, e.g. plastomer products under tradename QUEO™, supplied by Borealis, or Engage™ , supplied by ExxonMobil, Lucene supplied by LG, or Tafmer supplied by Mitsui. If present, then the amount of the optional plastomer is lower than the amount of the polymer of propylene (PP-C-a).

The optional functionalised polymer, if present, is a polymer which is functionalised e.g. by grafting. For instance, polar functional groups, such as maleic anhydride (MAH), can be grafted to a polyolefin to form functional polymers thereof. The random copolymer of propylene (PP-B-a) or the heterophasic copolymer of propylene (PP-B-b), is/are different from optional functionalised polymer. The random copolymer of propylene (PP-B-a) or the heterophasic copolymer of propylene (PP-B-b), is/are without grafted functional units. I.e. the term random copolymer of propylene (PP-B-a) or the heterophasic copolymer of propylene (PP-B-b), excludes the polymers of propylene grafted with functional groups. The amount of the optional functionalised polymer, if present, is preferably of 3 to 30 wt%, preferably 3 to 20 wt%, preferably 3 to 18 wt%, more preferably 4 to 15 wt%, based on the amount of the polypropylene composition (PP-B). If present, then the amount of the optional functionalised polymer(s) is less than the amount of the random copolymer of propylene (PP-B-a) or the heterophasic copolymer of propylene (PP-B-b).

The polypropylene composition (PP-B) preferably comprises, preferably consists of:
more than 25.0 wt%, preferably 30.0 to 98.8 wt%, preferably 30.0 to 98.5 wt%, of the random copolymer of propylene (PP-B-a) or the heterophasic copolymer of propylene (PP-B-b),
0.2 to 5.0 wt%, preferably of 0.5 to 5.0 wt%, of additives,
0 to 30.0 wt%, preferably 0 to 25.0 wt%, of filler(s),
0 to 50.0 wt% of further polymer component(s) which are different from the random copolymer of propylene (PP-B-a) or the heterophasic copolymer of propylene (PP-B-b),
0 to 5.0 wt%, preferably from 0.0001 to 5.0 wt% of an α-nucleating agent, preferably from 0.001 to 1.5 wt%, and especially preferably from 0.005 to 1.0 wt% of an α-nucleating agent,
based on the total amount of the polypropylene composition (PP-B).

The random copolymer of propylene (PP-B-a) or the heterophasic copolymer of propylene (PP-B-b), is then compounded together with the additives and optionally one or more of optional components as described above in a known manner. The compounding can be effected in a conventional extruder e.g. as described above and the obtained melt mix is produced to an article or, preferably, pelletised before used for the end application. Part or all of the additives or optional components may be added during the compounding step.

The polypropylene composition (PP-B) preferably has an MFR₂ (230° C., 2.16 kg) of 1.0 to 20.0 /10 min, more preferably of 1.5 to 18/10 min, still more preferably of 1.7 to 15 g/10 min, most preferably of 2.0 to 12 g/10 min.

The polypropylene composition (PP-B) of the invention preferably has a xylene cold soluble (XCS) content in amount of 10 to 40 wt%, more preferably 15 to 35 wt%, most preferably 15 to 30 wt%, based on the total amount of the polypropylene composition (PP-C).

The polypropylene composition (PP-B) preferably has a Vicat softening temperature (Vicat A) of 90 to 175° C., more preferably of 95 to 165° C., still more preferably of 100 to 160° C., most preferably of 105 to 155° C.

The polypropylene composition (PP-B) preferably has a melting temperature (Tm) of above 110° C., more preferably of 115 to 175° C., still more preferably of 120 to 175° C., most preferably of 125 to 170° C.

The polypropylene composition (PP-B) preferably has a crystallization temperature (Tc) of 90 to 150° C., more preferably of 95 to 145° C., still more preferably of 100 to 140° C., most preferably of 100 to 135° C.

The polypropylene composition (PP-B) preferably has a flexural modulus of at least 500 MPa, more preferably of 550 to 3000 MPa, still more preferably of 600 to 2700 MPa, most preferably of 650 to 2500 MPa.

The polypropylene composition (PP-B) preferably has a tensile modulus of at least 500 MPa, more preferably of 525 to 1500 MPa, when measured in machine direction from 200 µm monolayer cast film.

The polypropylene composition (PP-B) preferably has a tensile strength at least 20 MPa, more preferably of 25 to 75 MPa, when measured in machine direction from 250 µm monolayer cast film.

The polypropylene composition (PP-B) preferably has a tensile strain at break of at least 450%, more preferably of at least 500%, more preferably of 510 to 1500%, most preferably of 520 to 1200 %, when measured from 200 µm monolayer cast film.

Layer (B) preferably has a thickness of from 125 µm to 750 µm, more preferably from 150 µm to 650 µm, most preferably from 200 µm to 550 µm.

The layer (B) comprising the polypropylene composition (PP-B) shows a high total luminous transmittance. It has been found that a high total luminous transmittance of the polypropylene composition (PP-B) helps to improve the power output of a bifacial PV module using the polypropylene composition (PP-B) in its backsheet element on the rear side of the photovoltaic element.

The layer (B) has total luminous transmittance of at least 80%, preferably at least 85%, more preferably at least 89%.

The upper limit of the total luminous transmittance is usually not more than 99%, preferably not more than 97%.

Thereby, the total luminous transmittance not only depends on the optical properties of the polypropylene composition (PP-B) but also on the thickness of the layer. The thicker the layer the lower naturally is the total luminous transmittance.

For a layer (B) having a thickness of not more than 400 µm the total luminous transmittance is preferably at least 85%, more preferably at least 90%, still more preferably at least 92%.

For a layer (B) having a thickness of more than 400 µm the total luminous transmittance is preferably at least 80%, more preferably at least 85%, still more preferably at least 89%.

The layer (B) preferably has a clarity of at least 50%, more preferably at least 60%, still more preferably at least 70%.

The upper limit of the clarity is usually not more than 99%, preferably not more than 97%.

The layer (B) preferably has a haze of not more than 25%, more preferably not more than 22%, still more preferably not more than 20%.

The lower limit of the haze is usually at least 0.5%, preferably at least 1.0%.

### Layer (C)

In one embodiment the layer element comprises layer (C) in addition to layers (A) and (B).

Layer (C) comprises, preferably consists of the polyethylene composition (PE-C).

The polyethylene composition (PE-C) comprises a copolymer of ethylene, which is selected from
a copolymer of ethylene and comonomer units selected from one or more of alpha-olefins having from 3 to 12 carbon atoms (PE-C-a), which has a density of from 850 kg/m³ to 905 kg/m³; or
a copolymer of ethylene and comonomer units selected from one or more of alpha-olefins having from 3 to 12 carbon atoms, which additionally bears silane group(s) containing units (PE-C-b), having a density of from 850 kg/m³ to 905 kg/m³; or
a copolymer of ethylene and comonomer unit(s) selected from one or more of alpha-olefins having from 3 to 12 carbon atoms, which additionally bears functional group containing units originating from at least one unsaturated carboxylic acid and/or its anhydrides, metal salts, esters, amides or imides and mixtures thereof (PE-C-c), and has a density of from 850 kg/m³ to 905 kg/m³.

All alternative copolymers of ethylene (PE-C-a), (PE-C-b) and (PE-C-c) bear comonomer units selected one or more of alpha olefins having from 3 to 12 carbon atoms.

Suitable alpha-olefins having from 3 to 12 carbon atoms include 1-butene, 1-hexene and 1-octene, preferably 1-butene or 1-octene and more preferably 1-octene. Preferably copolymers of ethylene and 1-octene are used.

The copolymer of ethylene (PE-C-b) differs from the copolymer of ethylene (PE-C-a) in that it additionally bears silane group(s) containing units (PE-C-b).

The silane group(s) containing units are preferably grafted onto the polymeric backbone of the copolymer of ethylene (PE-C-b).

Preferably the silane group(s) containing units of the copolymer of ethylene (PE-C-b) are independently the same as the silane group(s) containing units of the copolymer of ethylene (PE-A-a) or copolymer of ethylene (PE-A-b) above.

Thus, all embodiments and amounts as described above for the silane group(s) containing units of the copolymer of ethylene (PE-A-a) or copolymer of ethylene (PE-A-b) also apply independently for the silane group(s) containing units (PE-C-b) with the exception that the silane group(s) containing units are preferably grafted onto the polymeric backbone of the copolymer of ethylene (PE-C-b).

The copolymer of ethylene (PE-C-b) preferably is a copolymer of ethylene and 1-butene, a copolymer of ethylene and 1-hexene or a copolymer of ethylene and 1-octene onto which silane group(s) containing units are grafted, most preferably a copolymer of ethylene and 1-octene onto which silane group(s) containing units are grafted.

It is especially preferred that the copolymer of ethylene (PE-C-b) preferably is a copolymer of ethylene and 1-butene, a copolymer of ethylene and 1-hexene or a copolymer of ethylene and 1-octene onto which silane group(s) containing units selected from vinyl trimethoxysilane, vinyl bismethoxyethoxysilane, vinyl triethoxysilane, more preferably vinyl trimethoxysilane or vinyl triethoxysilane are grafted, more preferably a copolymer of ethylene and 1-octene onto which silane group(s) containing units selected from vinyl trimethoxysilane, vinyl bismethoxyethoxysilane, vinyl triethoxysilane, more preferably vinyl trimethoxysilane or vinyl triethoxysilane are grafted.

Most preferred is a copolymer of ethylene and 1-octene onto which vinyl trimethoxysilane is grafted.

The copolymer of ethylene (PE-C-a) preferably is a copolymer of ethylene and 1-butene, a copolymer of ethylene and 1-hexene or a copolymer of ethylene and 1-octene, most preferably a copolymer of ethylene and 1-octene.

The copolymer of ethylene (PE-C-c) differs from the copolymer of ethylene (PE-C-a) in that it additionally bears functional group containing units originating from at least one unsaturated carboxylic acid and/or its anhydrides, metal salts, esters, amides or imides and mixtures thereof (PE-C-c).

The functional groups containing units are preferably grafted onto the polymeric backbone of the copolymer of ethylene (PE-C-c).

The functional groups containing units preferably originate from a compound selected from the group consisting of maleic anhydride, acrylic acid, methacrylic acid, crotonic acid, fumaric acid, fumaric acid anhydride, maleic acid, citraconic acid and mixtures thereof, preferably originating from maleic anhydride.

The amount of the functional groups containing units present in the based on the total amount of monomer units in the copolymer of ethylene (PE-C-c) is preferably in the range of from 0.01 to 1.5 mol%, more preferably from 0.01 to 1.00 mol%, still more from 0.02 to 0.80 mol%, even more preferably from 0.02 to 0.60 mol%, most preferably from 0.03 to 0.50 mol%, based on the total amount of monomer units in the copolymer of ethylene (PEC-c).

The copolymer of ethylene (PE-C-c) preferably is a copolymer of ethylene and 1-butene, a copolymer of ethylene and 1-hexene or a copolymer of ethylene and 1-octene onto which functional groups containing units are grafted, most preferably a copolymer of ethylene and 1-octene onto which functional groups containing units are grafted.

It is especially preferred that the copolymer of ethylene (PE-C-c) preferably is a copolymer of ethylene and 1-butene, a copolymer of ethylene and 1-hexene or a copolymer of ethylene and 1-octene onto which functional groups containing units originating from maleic anhydride, acrylic acid, methacrylic acid, crotonic acid, fumaric acid, fumaric acid anhydride, maleic acid, citraconic acid and mixtures thereof, more preferably maleic anhydride, are grafted, more preferably a copolymer of ethylene and 1-octene onto which functional groups containing units originating from maleic anhydride, acrylic acid, methacrylic acid, crotonic acid, fumaric acid, fumaric acid anhydride, maleic acid, citraconic acid and mixtures thereof, most preferably maleic anhydride, are grafted.

In a preferred embodiment the polyethylene composition (PE-C) comprises a copolymer of ethylene, which is selected from
a copolymer of ethylene and comonomer units selected from one or more of alpha-olefins having from 3 to 12 carbon atoms (PE-C-a), which has a density of from 850 kg/m³ to 905 kg/m³; or
a copolymer of ethylene and comonomer units selected from one or more of alpha-olefins having from 3 to 12 carbon atoms, which additionally bears silane group(s) containing units (PE-C-b), having a density of from 850 kg/m³ to 905 kg/m³.

The following properties characterize all alternative copolymers of ethylene (PE-C-a), (PE-C-b) and (PE-C-c):

The copolymer of ethylene is preferably an ethylene based plastomer.

The copolymer of ethylene has a density in the range of from 850 to 905 kg/m³, preferably in the range of from 855 to 900 kg/m³, more preferably in the range of from 860 to 895 kg/m³, most preferably in the range of from 865 to 890 kg/m³.

The MFR₂ of the copolymer of ethylene is preferably less than 20 g/min, more preferably less than 15 g/10 min, even more preferably from 0.1 to 13 g/10 min, still more preferably from 0.5 to 10 g/10 min, most preferably from 0.8 to 8.0 g/10 min.

The melting temperature of the copolymer of ethylene is preferably below 130° C., preferably below 120° C., more preferably below 110° C. and most preferably below 100° C.

Furthermore the copolymer of ethylene preferably has a glass transition temperature Tg (measured with DMTA according to ISO 6721-7) of below -25° C., preferably below -30° C., more preferably below -35° C.

The copolymer of ethylene preferably has an ethylene content from 55.0 to 95.0 wt%, preferably from 60.0 to 90.0 wt% and more preferably from 65.0 to 88.0 wt%.

The molecular mass distribution Mw/Mn of the copolymer of ethylene is most often below 4.0, such as 3.8 or below, but is at least 1.7. It is preferably between 3.5 and 1.8.

The copolymer of ethylene can be any copolymer of ethylene having the above defined properties, which are commercially available, i.a. from Borealis under the tradename Queo, from DOW under the tradename Engage or Affinity, or from Mitsui under the tradename Tafmer.

Alternately copolymer of ethylene can be prepared by known processes, in a one stage or two stage polymerization process, comprising solution polymerization, slurry polymerization, gas phase polymerization or combinations therefrom, in the presence of suitable catalysts, like vanadium oxide catalysts or single-site catalysts, e.g. metallocene or constrained geometry catalysts, known to the art skilled persons. Suitable polymerization processes are described in WO 2019/134904.

The polyethylene composition (PE-C) preferably comprises the copolymer of ethylene (PE-C-a), (PE-C-b) or (PE-C-c) in an amount of from 30.0 wt% to 100 wt%, more preferably from 30.0 wt% to 99.9999 wt%, still more preferably from 40.0 wt% to 99.999 wt% and most preferably from 50.0 wt% to 99.99 wt%, based on the total weight amount of the polyethylene composition (PE-C).

The amount of the copolymer of ethylene (PE-C-a), (PE-C-b) or (PE-C-c) in the polyethylene composition (PE-C) depends on the additional components in the polyethylene composition (PE-C).

The polyethylene composition (PE-C) suitably comprises additive(s) which are other than filler, pigment, carbon black or flame retardant which terms have a well-known meaning in the prior art.

The optional additives are preferably independently selected from the list of additives and in the amounts as described above for the polyethylene composition (PE-A).

The polyethylene composition (PE-C) can further comprise polymers, which are different from the copolymer of ethylene (PE-C-a), (PE-C-b) or (PE-C-c).

Said optional polymers are preferably selected from propylene based polymers or ethylene based polymers or mixtures thereof.

The optional propylene based polymers are preferably selected from propylene-alpha-olefin random copolymers and heterophasic copolymers of propylene or mixtures thereof.

The optional ethylene based polymers are preferably selected from ethylene-alpha-olefin copolymers or mixtures thereof.

The amount of polymers different from the copolymer of ethylene (PE-C-a), (PE-C-b) or (PE-C-c) is preferably in the range of from up to 50.0 wt%, such as 0.1 to 50.0 wt%, preferably 0.5 to 30.0 wt%, most preferably 1.0 to 10.0 wt%, based on the total weight amount of the polyethylene composition (PE-C).

It is preferred that the polyethylene composition (PE-C) is free of pigments, and/or flame retardants.

The polyethylene composition (PE-C) is preferably free of fillers as defined above or below for layers (A) and (B).

It is especially preferred that the polyethylene composition (PE-C) is free of fillers, pigments and/or flame retardants.

In one embodiment, the polyethylene composition (PE-C), comprises, preferably consists of, based on the amount (100 wt%) of the polyethylene composition (PE-C),
90.0 to 99.9999 wt%, preferably 95.0 to 99.999 wt%, most preferably 97.5 to 99.99 wt% of the copolymer of ethylene; and
0.0001 to 10.0 wt%, preferably 0.001 and 5.0 wt%, most preferably 0.01 and 2.5 wt%, of the additives.

In said embodiment the polyethylene composition (PE-C) usually has the same ranges of the properties of melt flow rate MFR₂, density, melting temperature Tm and glass transition temperature Tg as defined for the copolymer of ethylene (PE-C-a), (PE-C-b) or (PE-C-c) above.

In another embodiment, the polyethylene composition (PE-C) comprises additives as defined above also one or more polymer different to the copolymer of ethylene (PE-C-a), (PE-C-b) or (PE-C-c) as defined above. Then the polyethylene composition (PE-C) comprises, preferably consists of, based on the total amount (100 wt%) of the polyethylene composition (PE-C),
40.0 to 99.8999 wt%, preferably 65.0 to 99.499 wt%, most preferably 87.5 to 98.99 wt% of the copolymer of ethylene;
0.0001 to 10.0 wt%, preferably 0.001 and 5.0 wt%, most preferably 0.01 and 2.5 wt% of the additives; and
0.1 to 50.0 wt%, preferably 0.5 to 30.0 wt%, most preferably 1.0 to 10.0 wt% of the one or more different polymer.

In the presence of one or more different polymer the properties of the polyethylene composition (PE-C) usually are influenced not only by the properties of the copolymer of ethylene but also by the properties of the one or more different polymer. Thus, the properties of the polyethylene composition can differ from those of the copolymer of ethylene (PE-C-a), (PE-C-b) or (PE-C-c).

Preferably the layer (C) of the layer element consists of the polyethylene composition (PE-C) comprising the copolymer of ethylene as defined above, below or in claims.

Layer (C) preferably has a thickness of from 50 µm to 500 µm, preferably from 75 µm to 400 µm, most preferably from 100 µm to 300 µm.

### Process for Producing the Layer Element

The invention further provides a process for producing the layer element as defined above or below wherein the process comprises a step of:
adhering the layers (A), (B) and optional layer (C) of the layer element together by extrusion or lamination in the configuration A-B or A-C-B; and
recovering the formed layer element.

In one embodiment the layers (A) and (B) or layers (A), (B) and (C) of layer element are produced by extrusion, preferably by coextrusion.

The term “extrusion” means herein that the at least two layers of the layer element can be extruded in separate steps or in a same extrusion step, as well known in the art. One and preferable embodiment of the “extrusion” process for producing the at least three layers of the layer element is a coextrusion process. The term “coextrusion” means herein that the at least two layers, such as layers (A) and (B), or at least the three layers (A), (B) and (C) of the layer element can be coextruded in a same extrusion step, as well known in the art. The term “coextrusion” means herein that, in addition to said at least two layers (A) and (B) and optionally (C), also all or part of the additional layers of the layer element as described above, if present, can be formed simultaneously using one or more extrusion heads.

The extrusion and preferable coextrusion step can be carried out for example using a blown film or cast film extrusion process. Both processes have a well-known meaning and are well described in the literature of the field of the art.

Moreover, the extrusion step and the preferable coextrusion step, can be effected in any conventional film extruder, preferably in a conventional cast film extruder, e.g. in a single or twin screw extruder. Extruder equipments, like cast film extruder equipments, are well described in the literature and commercially available.

Other suitable extrusion techniques suitable for producing the layer element of the present invention are e.g. blown-film extrusion, such as blow-film coextrusion, and an extrusion process, such as a cast film extrusion process, preferably a cast film coextrusion process, with a subsequent calendaring process. These techniques are well known in the art.

The extrusion conditions are depend on the chosen layer materials and can be chosen by a skilled person.

Preferably the extrusion, preferably the coextrusion, of the layer element, is carried by cast film extrusion, preferably by cast film coextrusion.

In extrusion embodiment, in case of an adhesive layer between the adhering sides of the first and second layer, the adhesive layer is typically extruded or coextruded during the extrusion step of the first and second layer.

Part or all of said optional additional layer(s) of the layer element can be extruded, like coextruded, on the side of the layer (A) or the layer (B), or on the side of both the layer (A) and (B) which is not in adhering contact with one of layers (A), (B) or optional layer (C) as discussed above. The extrusion of said optional additional layer(s) can be carried out during the extrusion, preferably during the coextrusion, step layer (A) and layer (B). Alternatively or additionally, part or all of said optional additional layer(s) can be laminated to said opposite side of one or both of layer (A) and layer (B) after the extrusion, preferably coextrusion, step of layers (A), (B) and optional layer (C).

In an alternative embodiment, the layer element is produced by laminating at least two of the layers (A), (B) and optional layer (C) to an adhering contact. The lamination is carried out in a conventional lamination process using conventional lamination equipment well known in the art. In a typical lamination process, the separately formed layers of the layer element are arranged to form of the layer element assembly; then said layer element assembly is subjected to a heating step typically in a lamination chamber at evacuating conditions; after that said layer element assembly is subjected to a pressing step to build and keep pressure on the layer element assembly at the heated conditions for the lamination of the assembly to occur; and subsequently the layer element is subjected to a recovering step to cool and remove the obtained layer element.

Similarly in the alternative lamination embodiment, in addition to the layer (A), (B) and optional layer (C), the layer element may comprise further layer(s) on side opposite to adhering side of one or both of layers (A) and (B). In that case part or all of said optional additional layer(s) of the layer element can be laminated and/or extruded on the side of layer (A) or (B), or on the side of both the layers (A) and (B), which is not in adhering contact with one of layers (A), (B) or optional layer (C) as discussed above. Extrusion of optional additional layer(s) can be done before the lamination step of at least two of layers (A), (B) and optional layer (C). The lamination of optional additional layer(s) can be carried out in a step preceding the lamination step of at least two of layers (A), (B) and optional layer (C), during the lamination step of at least two of layers (A), (B) and optional layer (C), or after the lamination step of at least two of layers (A), (B) and optional layer (C).

In the alternative embodiment, wherein at least two of layers (A), (B) and optional layer (C) is produced by lamination, then layer (C) is applied using known techniques either on the surface of the layer (A) or on the surface of the layer (B).

The formed layer element can be further treated, if desired, for instance to improve the adhesion of the layer element or to modify the outer surfaces of the layer element. For example, the outer sides (opposite to “adhering” sides) of the layers (A) and (B), or in case of producing the layer element by lamination, then also the “adhering” sides of the layer which are laminated, can be surface treated using conventional techniques and equipments which are well-known for a skilled person.

The most preferred process for producing the layer element of the invention is said extrusion process, preferably said coextrusion process. More preferably, the extrusion process for producing the layer element is a cast film extrusion, most preferably a cast film coextrusion process.

Said extrusion process is especially suitable for the production of a layer element in which the polymers of the different layers show a comparable melting temperature. This means that coextrusion is especially suitable when for layer (A) the copolymers of ethylene (PE-A-a) and (PE-A-b) are used. Coextrusion is usually not suitable for layer elements in which for layer (A) the copolymer of ethylene (PE-A-c) used especially when crosslinked.

Accordingly, the preferred process for producing the layer element of the invention is an extrusion process, preferably a coextrusion process, which comprises the steps of:
mixing in separate mixing devices, preferably meltmixing in separate extruders, the polyethylene composition (PE-A) of layer (A), which preferably comprises one of copolymers of ethylene (PE-A-a) or (PE-A-b), the polypolypropylene composition (PP-B) of layer (B) and, optionally, the polyethylene composition (PE-C) of layer (C);
preparing at least separate layers (A) and (B) and optional (C) or at least separate layer (A) and coextruded layers (B) and (C) in the configuration B-C as such that layers (B) and (C) are in adherent contact with each other;
laminating at least the separate layers (A) and (B) to form a layer element of at least layers (A) and (B) in the configuration A-B, wherein said layers A and B are in adhering contact to each other, or at least separate layers (A), (B) and (C) in the configuration A-C-B, wherein said Layer (A) and (C) and layers (B) and (C) are in adhering contact to each other, or at least separate layers (A) and coextruded layers (B) and (C) in the configuration B-C in the configuration A-C-B, wherein said Layer (A) and (C) and layers (B) and (C) are in adhering contact to each other;
recovering the obtained layer element.

As well known a meltmix of the polymer composition or component(s) thereof is applied to form a layer. Meltmixing means herein mixing above the melting or softening point of at least the major polymer component(s) of the obtained mixture and is carried out for example, without limiting to, in a temperature of at least 10-15° C. above the melting or softening point of polymer component(s). The mixing step can be carried out in an extruder, like film extruder, e.g. in cast film extruder. The meltmixing step may comprise a separate mixing step in a separate mixer, e.g. kneader, arranged in connection and preceding the extruder of the layer element production line. Mixing in the preceding separate mixer can be carried out by mixing with or without external heating (heating with an external source) of the component(s).

In the above preferable process, the extrusion process is preferably a cast film extrusion, preferably a cast film coextrusion process. The extrusion process can also be a blown film extrusion process, preferably a blown film coextrusion process, or an extrusion process, such as a cast film extrusion process, preferably a cast film coextrusion process, with a subsequent calendaring process.

As said the extrusion process for forming the layer element of the invention can also comprise a further step subsequent to the extrusion, e.g. a further treatment step or lamination step, preferably subsequent to the extrusion step as described above.

In another preferred embodiment the layer element is produced by lamination as described above. This lamination process is especially suitable for layer elements in which the polymers of the different layers show different melting temperatures. This means that coextrusion is especially suitable when for layer (A) the copolymer of ethylene (PE-A-c) is used especially when crosslinked.

Accordingly, the preferred process for producing the layer element of the invention is lamination process, which comprises the steps of:
mixing in separate mixing devices, preferably meltmixing in separate extruders, the polyethylene composition (PE-A) of layer (A), which preferably comprises the copolymer of ethylene (PE-A-c), the polypropylene composition (PP-B) of layer (B) and, optionally, the polyethylene composition (PE-C) of layer (C);
applying, preferably applying simultaneously, the melt mix of the polyethylene composition (PE-A) of layer (A), the polypropylene composition (PP-B) of layer (B) and, optionally, the polyethylene composition (PE-C) of layer (C) via a die to form a layer element of at least layers (A) and (B) in the configuration A-B, wherein said layers A and B are in adhering contact to each other, or at least layers (A), (B) and (C) in the configuration A-C-B, wherein said Layer (A) and (C) and layers (B) and (C) are in adhering contact to each other;
recovering the obtained layer element.

As well known a meltmix of the polymer composition or component(s) thereof is applied to form a layer. Meltmixing means herein mixing above the melting or softening point of at least the major polymer component(s) of the obtained mixture and is carried out for example, without limiting to, in a temperature of at least 10-15° C. above the melting or softening point of polymer component(s). The mixing step can be carried out in an extruder, like film extruder, e.g. in cast film extruder. The meltmixing step may comprise a separate mixing step in a separate mixer, e.g. kneader, arranged in connection and preceding the extruder of the layer element production line. Mixing in the preceding separate mixer can be carried out by mixing with or without external heating (heating with an external source) of the component(s).

### Article

The article comprising the layer element can be any article wherein the properties of the layer element of the invention are for instance desirable or feasible.

The layer element can be part of an article or form the article, like film.

As non-limiting examples of such articles, extruded articles or moulded articles or combinations thereof can be mentioned. For instance the molded articles can be for packaging (including boxes, cases, containers, bottles etc), for household applications, for parts of vehicles, for construction and for electronic devices of any type. Extruded articles can be e.g. films of different types for any purposes, like plastic bags or packages, e.g. wrappers, shrink films etc.; electronic devices of any type; pipes etc., which comprise the layer element. The combinations of molded and extruded article are e.g. molded containers or bottles comprising an extruded label which comprises the layer element.

In one embodiment the article is a multilayer film comprising, preferably consisting of, the layer element. In this embodiment the layer element of the article is preferably a film for various end applications e.g. for packaging applications without limiting thereto. In this invention the term “film” covers also thicker sheet structures e.g. for thermoforming.

In a second embodiment the article is an assembly comprising two or more layer elements, wherein at least one layer element is the layer element of the invention.

The further layer element(s) of the assembly can be different or same as the layer element of the invention.

The second embodiment is the preferable embodiment of the invention.

The assembly of the preferable second embodiment is preferably a photovoltaic (PV) module comprising a photovoltaic element and one or more further layer elements, wherein at least one layer element is the layer element of the invention.

The preferred photovoltaic (PV) module of the invention comprises, in the given order, a protective front layer element, preferably a glass layer element, a front encapsulation layer element, a photovoltaic element, and the layer element (LE) of the invention.

In this preferable embodiment the layer element of the invention is multifunctional, i.e. the layer element of the invention functions both as a rear encapsulation layer element and as the protective back layer element. More preferably, layer (A) functions as an encapsulation layer element and layer (B) functions as the protective back layer element, which is also called herein as backsheet layer element. Optional layer (C) functions as adhesive layer in order to improve adhesion between the encapsulation layer element and the protective back layer element. Naturally, as said above under “Layer element of the invention”, there may be additional layers attached to the outer surface of Layer (A) to enhance the “encapsulation layer element” functionality. Further naturally, there may be additional layers attached to the outer surface of the layer (B) to enhance the “protective back layer element” functionality. Such additional layers can be introduced to layer (A) and, respectively, to layer (B) by extrusion, like coextrusion, or by lamination, or by combination thereof, in any order.

In the preferred photovoltaic (PV) module of the invention, the side of layer (A) opposite to side adhering to layer (B) or optional layer (C) is preferably in adhering contact with a photovoltaic element of the PV module.

Moreover, the side of layer (B) opposite to side adhering to layer (A) or optional layer (C) can be in adhering contact with further layers or layer elements, as known in the art of backsheet layer elements of PV module.

The final photovoltaic module can be rigid or flexible.

Moreover, the final PV module of the invention can for instance be arranged to a metal, such as aluminum, frame.

All said terms have a well-known meaning in the art.

The materials of the above elements of the above elements other than the layer element of the invention are well known in the prior art and can be chosen by a skilled person depending on the desired PV module.

The above exemplified layer elements other than the layer element of the invention can be monolayer or multilayer elements. Moreover, said other layer elements or part of the layers thereof can be produced by extrusion, e.g. coextrusion, by lamination, or by a combination of extrusion and lamination, in any order, depending on the desired end application, as well known in the art.

The “photovoltaic element” means that the element has photovoltaic activity. The photovoltaic element can be e.g. an element of photovoltaic cell(s), which has a well-known meaning in the art. Silicon based material, e.g. crystalline silicon, is a non-limiting example of materials used in photovoltaic cell(s). Crystalline silicon material can vary with respect to crystallinity and crystal size, as well known to a skilled person. Alternatively, the photovoltaic element can be a substrate layer on one surface of which a further layer or deposit with photovoltaic activity is subjected, for example a glass layer, wherein on one side thereof an ink material with photovoltaic activity is printed, or a substrate layer on one side thereof a material with photovoltaic activity is deposited. For instance, in well-known thin film solutions of photovoltaic elements e.g. an ink with photovoltaic activity is printed on one side of a substrate, which is typically a glass substrate.

The photovoltaic element is most preferably an element of photovoltaic cell(s).

“Photovoltaic cell(s)” means herein a layer element(s) of photovoltaic cells, as explained above, together with connectors.

The detailed description given above for layer element of the invention applies to layer element present in an article, preferable in a photovoltaic module.

In some embodiments of the PV module there can also be an adhesive layer between the different layer elements and/or between the layers of a multilayer element, as well known in the art. Such adhesive layers have the function to improve the adhesion between the two elements and have a well-known meaning in the lamination field. The adhesive layers are differentiated from the other functional layer elements of the PV module, e.g. those as specified above, below or in claims, as evident for a skilled person in the art.

Preferably, there is no adhesive layer between the photovoltaic element and the front encapsulation layer element. Alternatively, preferably there is no adhesive layer between the photovoltaic layer element and the layer element of the invention. More preferably, there is no adhesive layer between the photovoltaic element and the front encapsulation layer element and there is no adhesive layer between the photovoltaic layer element and the layer element of the invention.

As well-known in the PV field, the thickness of the above mentioned elements, as well as any additional elements, of an article, preferably of a laminated photovoltaic module, of the invention can vary depending on the desired end use application, like the desired photovoltaic module embodiment, and can be chosen accordingly by a person skilled in the PV field.

As a non-limiting example only, the thickness of a photovoltaic element, e.g. an element of monocrystalline photovoltaic cell(s), is typically between 100 to 500 microns.

The thickness of layer (A) of the layer element of the photovoltaic (PV) module of the invention, which preferably functions as a rear encapsulation layer element, can naturally vary depending on the desired PV module, as evident for a skilled person. Usually, the thickness of layer (A) is as defined above. The thickness of the rear encapsulation layer element which in addition to layer (A) can comprise further layer(s) (X), can typically be up to 2 mm, preferably up to 1 mm, typically 0.15 to 0.6 mm, when layer(s) (X) are present. As said, naturally, the thickness depends on the desired final end application and can be chosen by a skilled person.

Similarly, the thickness of the layer (B) of the layer element, which preferably functions as a protective back layer element (backsheet element) or part of such protective back layer element of the photovoltaic (PV) module of the invention, is usually as defined above together. The thickness of the protective back layer element, which in addition to layer (B) can comprise further layer(s) (Y), can naturally vary depending on the desired PV module application, as evident for a skilled person. As an example only, the thickness of protective back layer element of the preferable PV module can typically be up to 2 mm, preferably up to 1 mm, typically 0.15 to 0.6 mm, when layer(s) (Y) are present. Naturally, as said, the thickness depends on the desired final end application and can be chosen by a skilled person.

The photovoltaic module comprising the layer element of the present invention is preferably a bifacial photovoltaic module. This means that the photovoltaic cells of the photovoltaic element create photovoltaic activity on their front side and their rear side.

It is preferred that in the bifacial photovoltaic module the photovoltaic cells have contacts/busbars on both their front and rear sides.

The bifacial photovoltaic module comprising the layer element of the present invention show good power output on both the front and rear side of the photovoltaic element.

Preferably, the bifacial photovoltaic module has one or more of the following properties:
a short-circuit current I_{sc} of at least 5.00 A, preferably at least 5.50 A, more preferably at least 5.80 A, still more preferably at least 6.50 A and generally up to 12.00 A, preferably up to 10.00 A;
an open circuit voltage V_{oc} of at least 0.60 V, preferably of at least 0.62 V, more preferably of at least 0.63 V, still more preferably at least 0.65 V and generally up to 0.80 V, preferably up to 0.75 V;
a fill factor FF of at least 65.00%, preferably of at least 67.00%, more preferably of at least 69.00%, still more preferably at least 70.00% and generally up to 85.00%, preferably up to 80.00%; or
a maximum power Pₘₐₓ of at least 2.50 W, preferably of at least 2.75 W, more preferably of at least 3.00 W, still more preferably at least 3.25 W and generally up to 5.50 W, preferably up to 5.00 W;
when measured in a flash test on the front and rear side of the photovoltaic element.

On the front side of the photovoltaic element the bifacial photovoltaic module preferably has one or more of the following properties:
a short-circuit current I_{sc} of at least 8.00 A, preferably at least 8.50 A, more preferably at least 8.75 A and generally up to 12.00 A, preferably up to 10.00 A;
an open circuit voltage V_{oc} of at least 0.60 V, preferably of at least 0.62 V, more preferably of at least 0.63 V and generally up to 0.80 V, preferably up to 0.75 V;
a fill factor FF of at least 65.00%, preferably of at least 67.00%, more preferably of at least 69.00%, still more preferably at least 70.00% and generally up to 85.00%, preferably up to 80.00%; or
a maximum power Pₘₐₓ of at least 3.50 W, preferably of at least 3.75 W, more preferably of at least 4.00 W and generally up to 5.50 W, preferably up to 5.00 W;
when measured in a flash test on the front side of the photovoltaic element.

On the rear side of the photovoltaic element the bifacial photovoltaic module preferably has one or more of the following properties:
a short-circuit current I_{sc} of at least 5.00 A, preferably at least 5.50 A, more preferably at least 5.80 A, still more preferably at least 6.50 A and generally up to 10.00 A, preferably up to 8.00 A;
an open circuit voltage V_{oc} of at least 0.60 V, preferably of at least 0.62 V, more preferably of at least 0.63 V, still more preferably at least 0.65 V and generally up to 0.80 V, preferably up to 0.75 V;
a fill factor FF of at least 70.00%, preferably of at least 71.50%, more preferably of at least 72.50%, still more preferably at least 74.00% and generally up to 85.00%, preferably up to 80.00%; or
a maximum power Pₘₐₓ of at least 2.50 W, preferably of at least 2.75 W, more preferably of at least 3.00 W, still more preferably at least 3.25 W and generally up to 4.50 W, preferably up to 4.00 W;
when measured in a flash test on the rear side of the photovoltaic element.

The bifacial photovoltaic modules comprising the layer element of the present invention surprisingly show comparable power output on the rear side of the photovoltaic element as bifacial photovoltaic modules having a glass element as rear protective element but have a lower weight and are faster to laminate. The overall handling of the bifacial photovoltaic modules comprising the layer element of the present invention is also less laborious than bifacial photovoltaic modules having a glass element as rear protective element.

Compared to bifacial photovoltaic modules having a different polymeric material as rear protective element, such as PET or fluoropolymers, the bifacial photovoltaic modules comprising the layer element of the present invention shows an improved adhesion of the backsheet layer element (in the present case layer (B)) to the rear encapsulation layer element (in the present case layer (A)) and good recycling potential.

Additionally, the layer element of the invention, when measured on the laminate prepared as described in the example section, shows rather poor optical properties in regard of haze and clarity compared to the optical properties of layer (B). However, despite the poor optical properties of the layer element of the invention it has surprisingly been found that a bifacial PV module using the layer element on the rear side of the photovoltaic element as discussed above shows an unexpected improved power output of a bifacial PV module. The reason for this surprising effect seems to be found in the surprisingly high light transmittance through the layer element of the invention, when measured on the laminate prepared as described in the example section.

The layer element of the article, preferably of the photovoltaic module, can be produced as described above for the layer element of the invention.

The separate further elements of PV module other than the layer element of the invention can be produced in a manner well known in the photovoltaic field or are commercially available.

### Process for Preparing a Photovoltaic Module

The invention further provides a process for producing an assembly of the invention wherein the process comprises the steps of:
assembling the layer element of the invention and further layer element(s) to an assembly;
laminating the elements of the assembly in elevated temperature to adhere the elements together; and
recovering the obtained assembly.

The layer elements can be provided separately to the assembling step. Or, alternatively, part of the layer elements or part of the layers of two layer elements can be adhered together, i.e. integrated, already before providing to the assembling step.

The preferred process for producing the assembly is a process for producing a photovoltaic (PV) module by
assembling the photovoltaic element, the layer element of the invention and optional further layer elements to a photovoltaic (PV) module assembly;
laminating the layer elements of the photovoltaic (PV) module assembly in elevated temperature to adhere the elements together; and
recovering the obtained photovoltaic (PV) module.

The conventional conditions and conventional equipment are well known and described in the art of the photovoltaic module and can be chosen by a skilled person.

As said part of the layer elements can be in integrated form, i.e. two or more of said PV elements can be integrated together, e.g. by lamination, before subjecting to the lamination process of the invention.

Preferable embodiment of the process for forming the preferable photovoltaic (PV) module of the invention, is a lamination process comprising,
an assembling step to arrange a photovoltaic element and the layer element of the invention to form of a multilayer assembly, wherein layer (A) of the layer element is arranged in contact with the photovoltaic element, preferably an assembling step to arrange, in a given order, a front protective layer element, a front encapsulating layer element, a photovoltaic element and the layer element of the invention to form of a multilayer assembly, wherein layer (A) of the layer element is arranged in contact with a photovoltaic element;
a heating step to heat up the formed PV module assembly optionally, and preferably, in a chamber at evacuating conditions;
a pressing step to build and keep pressure on the PV module assembly at the heated conditions for the lamination of the assembly to occur; and
a recovering step to cool and remove the obtained PV module comprising the layer element.

The lamination process is carried out in laminator equipment, which can be e.g. any conventional laminator which is suitable for the multilaminate to be laminated, e.g. laminators conventionally used in the PV module production. The choice of the laminator is within the skills of a skilled person. Typically, the laminator comprises a chamber wherein the heating, optional, and preferable, evacuation, pressing and recovering (including cooling) steps take place.

### Use

The use of the layer element according to the invention as defined above or below as an integrated backsheet element of a bifacial photovoltaic module comprising a photovoltaic element and said layer element, wherein the photovoltaic element is in adhering contact with layer (A) of the layer element.

Thereby, the layer element and the photovolataic module preferably includes as the properties and definitions of the layer element and the photovolataic module as described above or below.

### EXAMPLES

### Determination Methods

Melt Flow Rate: The melt flow rate (MFR) is determined according to ISO 1133 and is indicated in g/10 min. The MFR is an indication of the flowability, and hence the processability, of the polymer. The higher the melt flow rate, the lower the viscosity of the polymer. The MFR₂ of polypropylene is measured at a temperature 230° C. and a load of 2.16 kg. The MFR₂ of polyethylene is measured at a temperature 190° C. and a load of 2.16 kg.

Density: ISO 1183, measured on compression moulded plaques.

### Comonomer Contents

The content (wt% and mol%) of polar comonomer present in the copolymer of ethylene (PE-A-b) and the content (wt% and mol%) of silane group(s) containing units present in the copolymers of ethylene (PE-A-a), (PE-A-b) and (PE-A-c) was determined as described in WO 2018/141672 for the content (wt% and mol%) of polar comonomer present in the polymer (a) and the content (wt% and mol%) of silane group(s) containing units (preferably comonomer) present in the polymer (a).
The alpha-olefin comonomer content present in copolymer of ethylene (PE-C-a), (PE-C-b) and (PE-C-c) was determined as described in WO 2019/134904 for the comonomer content quantification of poly(ethylene-co-1-octene) copolymers.
The comonomer content present in propylene polymer (PP-B-a) was determined as described in WO 2017/071847 for the comonomer content measurement.

### Rheological Properties

### Dynamic Shear Measurements (Frequency Sweep Measurements)

The rheological properties are measured as described in WO 2018/141672.

Melting temperature (Tₘ) and heat of fusion (H_{f}) were measured as described in WO 2018/141672.

Xylene cold soluble (XCS) was measured as described in WO 2018/141672.

Vicat softening temperature was measured according to ASTM D 1525 method A (50° C./h, 10 N).

Tensile Modulus; Tensile stress at yield and Tensile strain at break were measured as described in WO 2018/141672.

Flexural modulus was measured as described in WO 2017/071847.

### Monolayer and 3 Layer Film Preparation

Inventive monolayer cast films with 250 or 450 µm thickness were prepared on a Dr Collin extruder with 5 heating zones equipped with a PP screw with a diameter of 30 mm and LD of 30, a 300 mm die with a die gap of 0.5 mm. The melt temperature of 250° C. and a chill roll temperature of 20° C. were used.

Inventive 3-layer coextruded film samples were prepared on a Dr. Collin cast film line consisting of 3 automatically controlled extruders, a chill roll unit, a take-off unit with a cutting station and three winders to wrap the film and edge strips.

Each layer was extruded with an individual extruder: Two outer layers (layer A and layer B) were extruded with extruders equipped with 25 mm screw with LD of 30. The core layer (layer C) was extruded with extruder equipped with 30 mm screw with LD of 30. The thickness of each layer A was 250 µm, for each layer C was 200 µm and for each layer B was 250 µm resulting in a film thickness of the inventive layer elements 700 µm. The chill roll is cooled to 25° C. The melt temperature was 140-190° C. for polyethylene compositions (PE-A) and (PE-C) and 210-215° C. for the polypropylene compositions PP-B. The die width is 300 mm.

### Compression Moulding

The pellets of the test polyolefin composition were melted at 180° C. for 10 min between platen press Collin P 300 M under the pressure 0 bars. Then the pressure increased to 187 bars and elevated for 5 min. Then cooled down to room temperature at rate 15° C./min at 187 bars. The thickness of the plaque was around 0.5 mm.

### Power Output Measurement

Current-voltage (IV) characteristics of the 1-cell modules were obtained using a HALM cetisPV-Celltest3 flash tester. Prior to the measurements, the system was calibrated using a reference cell with known IV response. The 1-cell modules were flashed using a 30 ms light pulse from a xenon source. All results from the IV-measurements were automatically converted to standard test conditions (STC) at 25° C. by the software PV Control, available from HALM. Every sample setup was flashed three times on both sides of the bifacial module and given IV parameters are calculated average values of these three individual measurements. All modules were flash tested with a black mask when flashed from the front side. No mask was used when flashed from the rear side. The black mask was made out of standard black coloured paper and had a square-shaped opening of 160*160 mm. During flash test, the black mask was positioned in such way that the solar cell in the solar module was totally exposed to the flash pulse, and that there was 2 mm gap between the solar cell edges and the black mask. The black mask was fixated to the modules by using tape. All IV-characterization were done in accordance with the IEC 60904 series.

The retained Pmax is determined according to IEC 60904. Pmax is the power that the PV module generates from a flash pulse of 1000 W/m2 at standard test conditions (STC). From the IV-curve generated at the flash test, Pmax is obtained from the equation below where Isc is the short-circuit current, Voc is the open-circuit voltage and FF is the fill factor.

$${P}_{m a x} = {V}_{o c} ∗ {I}_{s c} ∗ F F$$

### Optical Properties

The total luminous transmittance, diffuse luminous transmittance and haze were measured according to ASTM D1003-13 (Method A-Hazemeter). The clarity is measured using the same machine and principle as haze but for angle less than 2.5° from normal. For clarity measurements, the specimens are positioned in the “clarity-port”. The measurement was performed as follows:
Device: Haze gard plus
Manufacturer: BYK-Gardner GmbH
Type:4725
Illuminant C

### Conditions

Conditioning time: > 96 h
Temperature: 23° C.
Test procedure: A - Hazemeter

### Experimental Part

### Polyethylene Compositions (PE-A) for Layer A

For layer A the following polyethylene compositions were used:

Polyethylene composition 1 (PE-A-1) is the polymer as described in example 1 in WO2019/158520 A1 (see Table 1 on page 43) which was blended with the additive INV.HALS1 mentioned on page 44 in Table 2.

Polyethylene composition 2 (PE-A-2) was prepared as described for modules 3 and 4 of an at the time of filing the present application unpublished international patent application (application number: PCT/EP2021/055764, filed on Mar. 8, 2021, page 31, Table 2A) of the same applicant as the present application.

Polyethylene composition 3 (PE-A-3) consists of the ethylene vinyl acetate copolymer (PE-A-c) composition EVA Hangzhou First F406P with 28% vinylacetate and MFR₂ = ca. 35 g/10 min, commercially available from Hangzhou First Applied Material Co., Ltd (PR China).

### Preparation of the Polypropylene Compositions (PP-B) for Layer B

The propylene random copolymers PP-B-a-A and PP-B-a-B are polymerized as shown below in Table 2.

As polymerization catalyst for PP-B-a-A the same metallocene catalyst system as for the polymerization of the inventive examples of WO 2019/215156 was used.

As polymerization catalyst for PP-B-a-B the following catalyst system was used:

### Preparation of the Catalyst Component for Olefin Polymerisation

(a) Acid and base treatment of ion-exchangeable layered silicate particles Benclay SL, whose major component is 2:1-layered montmorillonite (smectite), was purchased from Mizusawa Industrial Chemicals, Ltd, and used for catalyst preparation. Benclay SL has the following properties:
Dp50 = 46.9 µm
Chemical composition [wt.-%]: Al 9.09, Si 32.8, Fe 2.63, Mg 2.12, Na 2.39,
Al/Si 0.289 mol/mol

### Acid Treatment

To a 2L-flask equipped with a reflux condenser and a mechanical agitation unit, 1300 g of distilled water and 168 g of sulfuric acid (96%) were introduced. The mixture was heated to 95° C. by an oil bath, and 200 g of Benclay SL was added. Then the mixture was stirred at 95° C. for 840 min. The reaction was quenched by pouring the mixture into 2 L of pure water. The crude product was filtrated with a Buechner funnel connected with an aspirator and washed with 1 L of distilled water. Then the washed cake was re-dispersed in 902.1 g of distilled water. The pH of the dispersion was 1.7.

### Base Treatment

The aqueous solution of LiOH was prepared by solving 3.54 g of lithium hydroxide mono hydrate into 42.11 g of distilled water. Then the aqueous LiOH solution was introduced to a dropping funnel and dripped in the dispersion obtained above at 40° C. The mixture was stirred at 40° C. for 90 min. The pH of the dispersion was monitored through the reaction and stayed less than 8. The pH of the reaction mixture was 5.68. The crude product was filtrated with a Buechner funnel connected with an aspirator and washed 3 times with 2 L of distilled water each.

The chemically treated ion-exchangeable layered silicate particles were obtained by drying the above cake at 110° C. overnight. The yield was 140.8 g. Then the silicate particles were introduced into a 1 L-flask and heated to 200° C. under vacuum. After confirming that gas generation was stopped, the silicate particles were dried under vacuum at 200° C. for 2 h. The catalyst component for olefin polymerization of the present invention was obtained.

### Preparation of Olefin Polymerization Catalyst

### (B) Reaction With Organic Aluminum

To a 1000 ml-flask, 10 g of the chemically treated ion-exchangeable layered silicate particles obtained above (the catalyst component for olefin polymerization of the present invention) and 36 ml of heptane were introduced. To the flask, 64 ml of heptane solution of tri-n-octyl-alumiunum (TnOA), which includes 25 mmol of TnOA, was introduced. The mixture was stirred at ambient temperature for 1 h. The supernatant liquid was removed by decantation, and the solid material was washed twice with 900 ml of heptane. Then the total volume of reaction mixture was adjusted to 50 ml by adding heptane.

### (C) Prepolymerization

To the heptane slurry of the ion-exchangeable layered silicate particles treated with TnOA as described above, 31 ml of heptane solution of TnOA (12.2 mmol of TnOA) was added.

To a 200 ml flask, 283 mg of (r)-dichlorosilacyclobutylene-bis [2-(5-methyl-2-furyl)-4-(4-t-butylphenyl)-5,6-dimethyl-1-indenyl] zirconium (300 µmol) and 30 ml of toluene were introduced. Then the obtained complex solution was introduced to the heptane slurry of the silicate particles. The mixture was stirred at 40° C. for 60 min.

Then the mixture was introduced into a 1 L-autoclave with a mechanical stirrer, whose internal atmosphere was fully replaced with nitrogen in advance of use. The autoclave was heated to 40° C. After confirming the internal temperature was stable at 40° C., propylene was introduced at the rate of 10 g/h at 40° C. Propylene feeding was stopped after 2 h and the mixture was stirred at 40° C. for 1 h.

Then the residual propylene gas was purged out and reaction mixture was discharged into a glass flask. The supernatant solvent was discharged after settling enough. Then 8.3 ml of heptane solution of TiBAL (6 mmol) was added to the solid part. The mixture was dried under vacuum. The yield of solid catalyst for olefin polymerization (prepolymerized catalyst) was 35.83 g. Prepolymerization degree (the weight of prepolymer divided by the weight of solid catalyst) was 2.42.

TABLE 2

Polymerization, properties of propylene random copolymers PP-B-a-A and PP-B-a-B

| | PP-B-a-A | PP-B-a-B |
|---|---|---|
| Prepolymerisation | | |
| B1 Temperature [°C] | 25 | 20 |
| B1 residence time (h) | 0.3 | 0.44 |
| H2/C3 ratio (mol/kmol) | 0.03 | 0.29 |
| C2/C3 ratio (mol/kmol) | 36 | - |

| | | |
|---|---|---|
| Loop | | |
| B2 Temperature [°C] | 65 | 75 |
| B2 Pressure (barg) | 49 | 53 |
| B2 H2/C3 ratio [mol/kmol] | 0.11 | 0.19 |
| B2 C2/C3 ratio [mol/kmol] | 36 | - |
| B2 Split [%] | 57 | 37 |
| MFR, (g/10min) | 3.3 | 5.2 |
| C2 content | 3.7 | - |
| B3 Temperature [°C] | 80 | 80 |
| B3 Pressure [barg] | 24 | 24 |
| B3 H2/C3 ratio (mol/kmol) | 4.6 | 1.9 |
| B3 C2/C3 ratio [mol/kmol] | 109 | 165 |
| B3 split [%] | 43 | 63 |
| MFR₂ [g/10 min] | 2.0 | 2.7 |
| C2 content [wt.%] | 4.7 | 2.6 |
| XCS [wt.%] | 16 | 3.2 |
| Density [kg/m³] | 905 | 905 |

The heterophasic propylene copolymers PP-B-b-A and PP-B-b-B were polymerized as described for HECO A (PP-B-b-A) and HECO B (PP-B-b-B) in WO 2017/071847.

The powders of PP-B-a-A, PP-B-a-B, PP-B-b-A and PP-B-b-B were further melt homogenised and pelletized using a Coperion ZSK57 co-rotating twin screw extruder with screw diameter 20 57 mm and L/D 22. Screw speed was 200 rpm and barrel temperature 200-220° C. The following additives were added during the melt homogenisation step:

1500 ppm ADK-STAB A-612 (supplied by Adeka Corporation) and 300 ppm Synthetic hydrotalcite (ADK STAB HT supplied by Adeka Corporation).

### Compounding of the Layer B Examples

The compositions of PP-B-1 to PP-B4 were prepared by compounding the above mentioned propylene polymers PP-B-a-A, PP-B-a-B, PP-B-b-A and PP-B-b-B with the other components and conventional additives on a co-rotating twin-screw extruder (ZSK32, Coperion) using a screw speed of 400 rpm and a throughput of 90-100 kg/h. The melt temperature ranged from 210-230° C. The components and the amounts thereof are given below.

For polypropylene composition PP-B-1 99.6 wt% of PP-B-a-B was compounded with 0.4 wt% alpha nucleating agent Millad NX8000K, commercially available from Milliken Chemical

For polypropylene composition PP-B-2 the composition as described in example IE6 of WO 2017/071847 has been used.

The polypropylene composition thus includes
40.7 wt% heterophasic propylene copolymer B (PP-B-b-B),
27.2 wt% heterophasic propylene copolymer A (PP-B-b-A),
23 wt% talc,
8 wt% Queo 8230, supplier Borealis, is an ethylene based octene plastomer, produced in a solution polymerisation process using a metallocene catalyst, MFR₂ (190° C.) of 30 g/10 min and density of 882 kg/m³, and
1.1 wt% additives as described in the example section of WO 2017/071847. For polypropylene composition PP-B-3 99.6 wt% of PP-B-a-A was compounded with 0.4 wt% alpha nucleating agent Millad NX8000K, commercially available from Milliken Chemical.

For polypropylene composition PP-B-4 99.6 wt% of PP-B-b-A was compounded with 0.4 wt% alpha nucleating agent Millad NX8000K, commercially available from Milliken Chemical.

Polypropylene composition PP-B-5 consists of stabilised PP-B-b-A polymer as described above, without additional compounding step/additives etc.

### Preparation of the Polyethylene Compositions (PE-C) for Optional Layer C

Polyethylene composition 2 (PE-C-1) consists of Queo7007LA, which is an ethylene-based plastomer with 1-octene comonomer units having a melt flow rate MFR₂ (190° C., 2.16 kg) of 6.5 g/10 min and a density of 870 kg/m³ (including stabilizers), commercially available from Borealis AG. Queo7007LA is grafted with 1 wt% vinyl trimethoxy silane units (VTMS). The grafting is performed as described in the example section of WO 2019/201934.

Layer C in inventive examples is compression moulded 400 µm film if not otherwise mentioned.

### Mechanical Properties of the Compositions PP-B-1 to PP-B-5

The mechanical properties of the compositions PP-B-1 to PP-B-5 were determined and listed below in Table 3. Thereby, the tensile properties were measured on films having a thickness of 250 µm in machine direction (MD).

TABLE 3

Mechanical properties of the compositions PP-B-1 to PP-B-5

| | PP-B-1 | PP-B-2 | PP-B-3 | PP-B-4 | PP-B-5 |
|---|---|---|---|---|---|
| Tensile strain at break [%] | n.d. | 922 | 525 | 788 | 689 |
| Tensile modulus [MPa] | n.d. | 1221 | 540 | 982 | 1239 |
| Tensile strength [MPa] | n.d. | 27 | 27 | 48 | 30 |
| Vicat A [°C] | 122 | 134 | 108 | 151 | 153 |
| Tm [°C] | 153 | 167 | 133 | 167 | 167 |
| Tc [°C] | 125 | 129 | 103 | 131 | 129 |
| Flexural modulus [MPa] | 961 | n.d. | 683 | 1347 | 1357 |

n.d. = not determined

### Optical Properties of the Layers B

Optical properties are presented in table 4 for the inventive layer B compositions at different thicknesses. PP-B-1 is produced via compression moulding, while PP-B-2 to PP-B-5 are produced in monolayer cast film process as described above,

TABLE 4

Optical properties of layers B depending on their thickness

| | PP-B-1 | PP-B-2 | PP-B-3 | PP-B-3 | PP-B-4 | PP-B-4 | PP-B-5 |
|---|---|---|---|---|---|---|---|
| Thickness | 500 µm | 250 µm | 250 µm | 450 µm | 250 µm | 450 µm | 250 µm |
| Haze | 8.9% | 96.7% | 2.4% | 2.6% | 8.0% | 17.3% | 21.7% |
| Clarity | 53.1% | 4.9% | 96.6% | 96.6% | 92.1% | 73.3% | 92.0% |
| diffuse luminous transmittance | 8.2% | 78.4% | 2.3% | 2.5% | 7.5% | 15.5% | 21.4% |
| total luminous transmittance | 92.7% | 81.1% | 94.7% | 93.8% | 92.8% | 89.5% | 90.0% |

### Preparation of the Layer Elements

Layer elements were produced from the compositions PE-A, PP-B and optionally PE-C as listed below in Table 1.

Thereby, in all layer elements layer (A) has a thickness of 450 µm.

Optional layer (C), where present, has a thickness of 400 µm or 200 µm (LE2 and LE3).

The thickness of layer (B) varies for the different layer elements in the range of 250 µm and 500 µm and is disclosed below in Table 5.

TABLE 5

Composition of layer elements (LE) and thickness of layers

| | | | | |
|---|---|---|---|---|
| | Layer A | Layer C | Layer B | Thickness layer B |
| Inv. LE1 | PE-A-1 | PE-C-1 | PP-B-1 | 500 µm |
| Inv. LE2 | PE-A-1 | PE-C-1 | PP-B-2 | 250 µm |
| Inv. LE3 | PE-A-1 | - | PP-B-3 | 250 µm |
| Inv. LE4 | PE-A-1 | - | PP-B-3 | 450 µm |
| Inv. LE5 | PE-A-1 | - | PP-B-4 | 250 µm |
| Inv. LE6 | PE-A-1 | - | PP-B-4 | 450 µm |
| Inv. LE7 | PE-A-1 | - | PP-B-5 | 250 µm |
| Inv. LE8 | PE-A-1 | - | PP-B-2 | 250 µm |
| Inv. LE9 | PE-A-3 | - | PP-B-3 | 250 µm |
| Inv. LE10 | PE-A-3 | - | PP-B-2 | 250 µm |
| Inv. LE11 | PE-A-1 | PE-C-1 | PP-B-3 | 250 µm |
| Inv. LE12 | PE-A-1 | PE-C-1 | PP-B-3 | 450 µm |
| Inv. LE13 | PE-A-1 | PE-C-1 | PP-B-4 | 250 µm |
| Inv. LE14 | PE-A-1 | PE-C-1 | PP-B-4 | 450 µm |
| Inv. LE15 | PE-A-1 | PE-C-1 | PP-B-5 | 250 µm |

Layer element Inv. LE2 was produced by the following coextrusion process: 3-layer calendar films for the inventive layer element Inv. LE2 was prepared on a Dr. Collin cast film

The thickness of layer A was 250 µm, for layer C was 200 µm and for layer B was 250 µm resulting in a film thickness of the inventive layer element Inv. LE2 of 700 µm.

The layer A were extruded onto the embossed side of the calendar-unit and the layers B were extruded onto the smooth side of the calendar-unit with the layers C sandwiched by layers A and B. The chill roll is cooled to 25° C. The melt temperature was 140-190° C. for polyethylene compositions (PE-A) and (PE-C) and 210-215° C. for the polypropylene compositions PP-B.

All other layer elements were produced during lamination of the PV minimodules by the lamination process as described below.

### Preparation of PV Minimodules

For the PV modules comprising the layer elements as described above as integrated backsheet elements 300 mm × 200 mm laminates consisting of Glass/Encapsulant/Cell with connectors/layer element as described above were prepared using a PEnergy L036LAB vacuum laminator.

Glass layer, structured solar glass, low iron glass, supplied by InterFloat, length: 300 mm and width: 200 mm, total thickness of 3.2 mm.

The front protective glass element was cleaned with isopropanol before putting the first encapsulation layer element film on the solar glass. The front encapsulation layer element was cut in the same dimension as the solar glass element. After the front encapsulation layer element was put on the front protective glass element, then the soldered solar cell was put on the front encapsulation layer element. Further the layer element of the invention was put on the obtained PV cell element. The obtained PV module assembly was then subjected to a lamination process as described below.

TABLE 6

Lamination settings for photovoltaic modules

| Module type | Temperature [°C] | Pressure [mbar] step (iv) | Heating (i), s | Evacuation (ii) [s] | Pressure build-up of pressing step (iii) [s] | Pressure holding sub step of pressing step (iv) [s] | Total time of steps (i) to (iv) [s] |
|---|---|---|---|---|---|---|---|
| Glass/Glass | 150 | 800-900 | 0 | 300 | 10 | 900 | 1210 |
| Glass/Layer Element | 150 | 800-900 | 0 | 300 | 10 | 600 | 910 |

As front encapsulants the compositions PE-A-1, PE-A-2 and PE-A-3 as described above for layer (A) were used. The thickness of all front encapsulants was 450 µm. The same type of structured solar glass having a thickness of 3.2 mm (Ducat) was used for all cells.

For examples CE1, IE1, IE2 and IE3 as photovoltaic cell a P-type mono crystalline silica cell with five buss-bars and having a dimension of 156×156 mm (pseudosquare). The cell was supplied by Trina Solar. The composition of the soldering wire was Sn:Pb:Ag (62:36:2).

For all other examples as photovoltaic cell a P-type mono crystalline silica cell with five buss-bars and having a dimension of 156×156 mm was used. The cell was supplied by LightWay. The composition of the soldering wire was Sn:Pb:Ag (62:36:2).

For comparative examples CE1 and CE2 the same structured solar glass as for the front glass layer was also used as rear glass layer.

For the inventive examples the layer elements prepared as described above are used.

The vacuum lamination occurred at 150° C. using a lamination program of 5 minutes evacuation time, followed by 15 minutes pressing time with an upper chamber pressure of 800 mbar.

The composition of the PV modules of the examples are shown in Table 7.

TABLE 7

Layers used in the PV modules of the examples CE1-2 and IE1-16

| | | | |
|---|---|---|---|
| | Front encapsulant | Rear encapsulant | Rear protection |
| CE1 | PE-A-2 | PE-A-2 | glass |
| CE2 | PE-A-1 | PE-A-1 | glass |
| IE1 | PE-A-1 | - | Inv. LE1 |
| IE2 | PE-A-1 | - | Inv. LE2 |
| IE3 | PE-A-3 | - | Inv. LE2 |
| IE4 | PE-A-1 | - | Inv. LE3 |
| IE5 | PE-A-1 | - | Inv. LE4 |
| IE6 | PE-A-1 | - | Inv. LE5 |
| IE7 | PE-A-1 | - | Inv. LE6 |
| IE8 | PE-A-1 | - | Inv. LE7 |
| IE9 | PE-A-1 | - | Inv. LE8 |
| IE10 | PE-A-3 | - | Inv. LE9 |
| IE11 | PE-A-3 | - | Inv. LE10 |
| IE12 | PE-A-1 | - | Inv. LE11 |
| IE13 | PE-A-1 | - | Inv. LE12 |
| IE14 | PE-A-1 | - | Inv. LE13 |
| IE15 | PE-A-1 | - | Inv. LE14 |
| IE16 | PE-A-1 | - | Inv. LE15 |

The power output (front flash and rear flash only) for the produced PV modules was tested and reported in Table 8. RE1 shows the power output of the unlaminated (“naked”) bifacial solar cell used for most of the examples (with the exception of examples CE1, IE1, IE2 and IE3).

TABLE 8

Power output of the PV modules

| Examples | Isc, A | Voc, V | FF, % | Pmax, W |
|---|---|---|---|---|
| RE1, front/rear | 9.16 / 6.67 | 0.67 / 0.66 | 73.57 / 75.97 | 4.51 / 3.35 |
| CE1, front/rear | 9.05 / 5.85 | 0.66 / 0.65 | 72.64 / 74.94 | 4.34 / 2.84 |
| CE2, front/rear | 9.10 / 7.26 | 0.67 / 0.66 | 74.10 / 75.73 | 4.50 / 3.64 |
| IE1, front/rear | 9.04 / 5.82 | 0.66 / 0.65 | 72.96 / 75.72 | 4.36 / 2.86 |
| IE2, front/rear | 8.97 / 5.52 | 0.66 / 0.64 | 73.27 / 75.92 | 4.32 / 2.69 |
| IE3, front/rear | 9.03 / 5.54 | 0.66 / 0.65 | 73.44 / 76.10 | 4.37 / 2.72 |
| IE4, front/rear | 8.98 / 7.07 | 0.66 / 0.65 | 73.79 / 75.37 | 4.38 / 3.49 |
| IE5, front/rear | 9.03 / 7.25 | 0.67 / 0.66 | 73.80 / 75.50 | 4.46 / 3.63 |
| IE6, front/rear | 9.00 / 7.24 | 0.67 / 0.66 | 70.39 / 75.56 | 4.23 / 3.62 |
| IE7, front/rear | 8.98 / 7.07 | 0.66 / 0.66 | 74.18 / 75.85 | 4.42 / 3.52 |
| IE8, front/rear | 9.00 / 7.09 | 0.67 / 0.66 | 73.34 / 74.97 | 4.39 / 3.50 |
| IE9, front/rear | 9.00 / 6.25 | 0.66 / 0.65 | 73.66 / 76.05 | 4.40 / 3.11 |
| IE10, front/rear | 8.95 / 6.72 | 0.66 / 0.65 | 73.78 / 75.71 | 4.36 / 3.33 |
| IE11, front/rear | 9.02 / 6.25 | 0.67 / 0.65 | 73.08 / 75.31 | 4.39 / 3.08 |
| IE12, front/rear | 8.98 / 6.93 | 0.66 / 0.65 | 73.86 / 75.84 | 4.39 / 3.44 |
| IE13, front/rear | 8.94 / 6.76 | 0.66 / 0.66 | 73.93 / 75.88 | 4.38 / 3.36 |
| IE14, front/rear | 9.04 / 7.22 | 0.67 / 0.66 | 73.63 / 75.36 | 4.43 / 3.60 |
| IE15, front/rear | 8.97 / 6.81 | 0.66 / 0.65 | 74.27 / 76.13 | 4.40 / 3.39 |
| IE16, front/rear | 9.01 / 7.05 | 0.67 / 0.66 | 73.83 / 75.52 | 4.43 / 3.51 |

Preparation of laminates for measurement of the optical properties:

For measuring the optical properties (clarity, haze, diffuse luminous transmittance and total luminous transmittance) of the inventive laminates I-Lam1-10 300 mm × 200 mm laminates consisting of Glass/teflon film/layer element/teflon film/glass were prepared using a PEnergy L036LAB vacuum laminator.

For the Reference laminate, simulating the rear side of glass-glass module RE-Lam a 300 mm × 200 mm laminate consisting of Glass/PE-A-⅟teflon film/glass was prepared using a PEnergy L036LAB vacuum laminator.

Glass layer: solar glass GMB SINA, thickness 3.2 mm, commercially available from Interfloat Corporation

Teflon film: Fluteck P1000, thickness 50 µm, commercially available from Vital Polymers

PE-A-1: as described above, thickness 450 µm.

The vacuum lamination occurred at 150° C. using a lamination program of 5 minutes evacuation time, followed by 15 minutes pressing time with an upper chamber pressure of 800 mbar.

After lamination the glass layers and the teflon films are removed from both sides of the inventive laminates whereas the glass layer and the teflon film are removed from the one side of the reference laminate.

The optical properties (clarity, haze, diffuse luminous transmittance and total luminous transmittance) of the produced laminates (without glass layers for the inventive laminates and with a glass layer on one side of the reference laminate presenting the rear side of a glass-glass PV module) was tested and reported in Table 9 together with the thickness of the laminates.

TABLE 9

Composition, thickness and optical properties of laminates

| examples | layer element | clarity [%] | haze [%] | diffuse luminous transmittance [%] | total luminous transmittance [%] | Thickness [mm] |
|---|---|---|---|---|---|---|
| Ref-Lam | Glass/PE- A-1 | 44.6 | 46.0 | 41.3 | 89.8 | 3.5874 |
| I-Lam 1 | Inv LE3 | 35.3 | 69.8 | 63.4 | 90.9 | 0.7050 |
| I-Lam2 | Inv LE4 | 8.7 | 87.4 | 77.6 | 88.9 | 0.9993 |
| I-Lam3 | Inv LE5 | 16.1 | 81.8 | 71.5 | 87.4 | 0.7244 |
| I-Lam4 | Inv LE6 | 17.3 | 82.5 | 67.5 | 81.9 | 1.0860 |
| I-Lam5 | Inv LE7 | 22.8 | 79.5 | 67.9 | 85.4 | 0.8055 |
| I-Lam6 | Inv LE8 | 7.2 | 97.3 | 71.6 | 73.6 | 0.7147 |
| I-Lam7 | Inv LE9 | 34.3 | 63.4 | 60.1 | 94.7 | 0.6993 |
| I-Lam8 | Inv LE10 | 5.9 | 96.8 | 73.5 | 75.9 | 0.6352 |
| I-Lam9 | Inv LE11 | 29.7 | 76.8 | 68.1 | 88.8 | 1.0709 |
| I-Lam10 | Inv LE13 | 19.6 | 66.2 | 57.6 | 87.0 | 1.1559 |

It can be seen that despite of poor optical properties in behalf of low clarity, high haze surprisingly high diffuse and total luminous transmittance can be obtained for laminates of the invention.

1. A layer element comprising at least two layers (A) and (B), wherein layer (A) comprises a polyethylene composition (PE-A) comprising
(PE-A-a) a copolymer of ethylene, which bears silane group(s) containing units; or
(PE-A-b) a copolymer of ethylene with polar comonomer units selected from one or more of (C₁-C₆)-alkyl acrylate or (C₁-C₆)-alkyl (C₁-C₆)-alkylacrylate comonomer units, which additionally bears silane group(s) containing units,
wherein the copolymer of ethylene (PE-A-a) is different from the copolymer of ethylene (PE-A-b); or
(PE-A-c) a copolymer of ethylene with vinyl acetate comonomer units; and
layer (B) comprises a polypropylene composition (PP-B) comprising
(PP-B-a) a random copolymer of propylene monomer units with alpha olefin comonomer units selected from ethylene and alpha-olefins having from 4 to 12 carbon atoms; or
(PP-B-b)) a heterophasic copolymer of propylene which comprises,
a polypropylene matrix component and
an elastomeric propylene copolymer component which is dispersed in said polypropylene matrix;
wherein layer (B) has a total luminous transmittance of at least 80.0%.

2. The layer element according to claim 1, wherein the polypropylene composition of layer (B) comprises a nucleating agent.

3. The layer element according to claim 2, wherein the nucleating agent is selected from polymeric nucleating agents and soluble nucleating agents or mixtures thereof.

4. The layer element according to claim 1, wherein the layers (A) and (B) are in adherent contact with each other in the configuration A-B.

5. The layer element according to claim 1 further comprising a layer (C), which comprises a polyethylene composition (PE-C) comprising a copolymer of ethylene, which is selected from
(PE-C-a) a copolymer of ethylene and comonomer units selected from one or more alpha-olefins having from 3 to 12 carbon atoms, which has a density of from 850 kg/m³ to 905 kg/m³; or
(PE-C-b) a copolymer of ethylene and comonomer units selected from one or more of alpha-olefins having from 3 to 12 carbon atoms, which additionally bears silane group(s) containing units, having a density of from 850 kg/m³ to 905 kg/m³; or
(PE-C-c) a copolymer of ethylene and comonomer units selected from one or more of alpha-olefins having from 3 to 12 carbon atoms, which additionally bears functional group containing units originating from at least one unsaturated carboxylic acid and/or its anhydrides, metal salts, esters, amides or imides and mixtures thereof;
wherein layers (A) and (C) and layers (B) and (C) are in adhering contact with each other in the configuration A-C-B.

6. The layer element according to claim 1, wherein all layers of the layer element are free of titanium dioxide, preferably free of pigment.

7. The layer element according to claim 1, wherein the layer element has a total thickness of from 325 µm to 2000 µm.

8. The layer element according to claim 1, wherein layer (A) has a thickness of from 100 µm to 750 µm, layer (B) has a thickness of from 125 µm to 750 µm, and optional layer (C) has a thickness of from 50 µm to 500 µm.

9. An article comprising the layer element according to claim 1 .

10. The article according to claim 9 being a photovoltaic module comprising a photovoltaic element and the layer element wherein the photovoltaic element is in adhering contact with layer (A) of the layer element.

11. The article according to claim 10, which comprises, in the given order, a protective front layer element, a front encapsulation layer element, a photovoltaic element and an integrated backsheet element, wherein the integrated backsheet element comprises, preferably consists of the layer element.

12. The article, being a photovoltaic module according to claim 10 having one or more of the following properties:
a short-circuit current I_{sc} of at least 5.00 A,
an open circuit voltage V_{oc} of at least 0.60 V,
a fill factor FF of at least 70.00%, or
a maximum power Pₘₐₓ of at least 2.50 W,
when measured in a flash test on the front and rear side of the photovoltaic element.

13. A process for producing the layer element according to claim 1 comprising the steps of:
adhering the layers (A), (B) and optional layer (C) of the layer element together by extrusion or lamination in the configuration A-B or A-C-B; and
recovering the formed layer element.

14. A process for producing a photovoltaic (PV) module according claim 10 comprising:
assembling the photovoltaic element, the layer element and optional further layer elements to a photovoltaic (PV) module assembly;
laminating the layer elements of the photovoltaic (PV) module assembly in elevated temperature to adhere the elements together; and
recovering the obtained photovoltaic (PV) module.

15. (canceled)

16. The article according to claim 10, wherein the layer element is an integrated backsheet element of a bifacial photovoltaic module comprising a photovoltaic element and said layer element.
